(19) United States
(12) Patent Application Publication
(10) Pub. No.: US 2015/0370313 A1
(43) Pub. Date: Dec. 24, 2015

(54) SEMICONDUCTOR DEVICE

(71) Applicant: Semiconductor Energy Laboratory Co., Ltd., Atsugi-shi (JP)

(72) Inventor: Hikaru TAMURA, Hadano (JP)

(21) Appl. No.: 14/741,910

(22) Filed: Jun. 17, 2015

(30) Foreign Application Priority Data
Jun. 20, 2014 (JP) 2014-127211
Aug. 19, 2014 (JP) 2014-167002

(51) Int. Cl. G06F 1/32; H01L 27/12; H01L 29/786; G06F 11/14

(52) U.S. Cl. CPC G06F 1/3296; G06F 11/1456; H01L 27/1255; H01L 29/7869

(57) ABSTRACT

Power consumption is reduced. A semiconductor device includes an arithmetic processing circuit, a power supply circuit, a power management unit (PMU), and a power switch. The arithmetic processing circuit includes a storage circuit for retaining generated data. The storage circuit includes a backup circuit including a transistor and a capacitor. When a control signal for transition to a resting state is input from the arithmetic processing circuit to the PMU, the PMU performs voltage scaling operation for lowering the power supply potential of the arithmetic processing circuit. When the time of the voltage scaling operation is longer than the time of the resting state, the PMU performs power gating operation for stopping supply of power to the arithmetic processing circuit. The storage circuit performs data backup operation before the PMU performs the voltage scaling operation.

### TECHNICAL FIELD

One embodiment of the present invention relates to a semiconductor device such as a circuit, a processing circuit, or a storage circuit including a semiconductor, a driving method thereof, a manufacturing method thereof, and the like.

The present invention is not limited to the above technical field. The technical field of one embodiment of the invention disclosed in the specification, the drawings, and the claims (hereinafter referred to as “this specification and the like”) relates to an object, a method, or a manufacturing method. Furthermore, one embodiment of the present invention relates to a process, a machine, manufacture, or a composition of matter. Specifically, examples of the technical field of one embodiment of the present invention disclosed in this specification and the like include a semiconductor device, a processing unit, a storage device, a display device, a liquid crystal display device, a light-emitting device, a lighting device, a power storage device, an input device, an imaging device, a driving method thereof, and a manufacturing method thereof.

### BACKGROUND ART

A transistor in which a channel is formed using an oxide semiconductor such as an In—Ga—Zn oxide (In—Ga—Zn—O) (hereinafter such a transistor is sometimes referred to as an OS transistor) is known. In addition, it is known that an OS transistor has extremely low off-state current because an oxide semiconductor has a wider bandgap than silicon. A variety of semiconductor devices that utilize off-state current characteristics of OS transistors have been proposed. For example, Patent Documents 1 and 2 disclose storage circuits.

As techniques for reducing the power consumption of semiconductor devices, power gating, clock gating, and voltage scaling are known, for example. Patent Document 3 discloses a technique for effectively reducing power consumption among dynamic voltage and frequency scaling (DVFS) techniques and power gating (PG) techniques, for example.

### REFERENCE

Patent Document 1: Japanese Published Patent Application No. 2013-008437
Patent Document 2: Japanese Published Patent Application No. 2013-009297
Patent Document 3: PCT International Publication No. WO 2009/078081

### DISCLOSURE OF INVENTION

It is an object of one embodiment of the present invention to provide a novel semiconductor device or a method for operating the novel semiconductor device. It is an object of one embodiment of the present invention to reduce power consumption, for example, reduce power in a resting state. It is an object of one embodiment of the present invention to shorten time needed to perform processing for transition from a resting state to a normal state or reduce energy needed to perform the processing.

Note that the description of a plurality of objects does not disturb the existence of each object. One embodiment of the present invention does not necessarily achieve all the objects described above. Other objects will be apparent from and can be derived from the description of the specification, the drawings, the claims, and the like, and such objects could be objects of one embodiment of the present invention.

One embodiment of the present invention is a semiconductor device that includes a power supply circuit, a power management unit, an arithmetic processing circuit, and a power switch. The power supply circuit has a function of generating a power supply potential. The power switch has a function of controlling supply of the power supply potential to the arithmetic processing circuit. The arithmetic processing circuit includes a first circuit and a second circuit. The first circuit is capable of retaining data generated in the arithmetic processing circuit. The second circuit is capable of backing up and retaining data retained in the first circuit and capable of restoring backed up data to the first circuit. The power management unit is capable of controlling data backup operation from the first circuit to the second circuit, capable of controlling data restore operation from the second circuit to the first circuit, capable of controlling operation of the power switch, and capable of controlling a change in the value of the power supply potential generated in the power supply circuit.

One embodiment of the present invention is a semiconductor device that includes a power supply circuit, a power management unit, an arithmetic processing circuit, and a power switch. The arithmetic processing circuit includes a first circuit and a second circuit. The first circuit is capable of retaining data generated in the arithmetic processing circuit. The second circuit is capable of backing up and retaining data retained in the first circuit and capable of restoring backed up data to the first circuit. The power switch is capable of controlling supply of a power supply potential generated in the power supply circuit to the arithmetic processing circuit. The power supply circuit is capable of generating a first power supply potential and a second power supply potential. The power management unit is capable of controlling supply of a power supply potential to the arithmetic processing circuit by controlling operation of the power supply circuit and the power switch. The power management unit has at least three power management modes of first to third modes. The first mode is a mode in which the first power supply potential is supplied. The second mode is a mode in which the second power supply potential is supplied. The third mode is a mode in which supply of the first and second power supply potentials is stopped. The second power supply potential is lower than the first power supply potential and capable of erasing data retained in the first circuit. The power management unit includes a third circuit capable of measuring time. The power management unit is capable of transferring from the first mode to the second mode in response to a first signal generated in the arithmetic processing circuit, capable of controlling data backup operation from the first circuit to the second circuit in response to the first signal, capable of transferring from the second mode to the third mode in response to a second signal generated in the third circuit, capable of transferring from the third mode to the first mode in response to a third signal, and capable of controlling data restore operation from the second circuit to the first circuit in response to the third signal.

In the above embodiment, the first circuit can be a flip-flop circuit. Alternatively, in the above embodiment, the second circuit may include the first transistor and a capacitor. The capacitor may be electrically connected to a source or a drain of the first transistor. Conduction of the first transistor may be controlled by the power management unit. A channel of the first transistor may include an oxide semiconductor.

In this specification and the like, ordinal numbers such as “first”, “second”, and “third” are used to avoid confusion among components, and thus do not limit the number of components or do not limit the order.

In this specification and the like, a semiconductor device refers to a device that utilizes semiconductor characteristics, and means a circuit including a semiconductor element (e.g., a transistor or a diode), a device including the circuit, and the like. The semiconductor device also means any device that can function by utilizing semiconductor characteristics. For example, an integrated circuit and a chip including an integrated circuit are all semiconductor devices. Moreover, a storage device, a display device, a light-emitting device, a lighting device, an electronic device, and the like themselves might be semiconductor devices, or might each include a semiconductor device.

Note that a transistor is an element having three terminals (nodes): a gate, a source, and a drain. The gate functions as a control terminal for controlling conduction of the transistor. Depending on the type of the transistor or levels of potentials applied to the terminals (nodes), one of a pair of input/output terminals (nodes) functions as a source and the other functions as a drain. In general, in an n-channel transistor, a node to which a low potential is applied is referred to as a source, and a node to which a high potential is applied is referred to as a drain. In contrast, in a p-channel transistor, a node to which a low potential is applied is referred to as a drain, and a node to which a high potential is applied is referred to as a source. In this specification, two terminals (nodes) except a gate are referred to as a first terminal (node) and a second terminal (node) in some cases.

In this specification, to clarify a circuit configuration and circuit operation, one of input/output terminals (nodes) of a transistor is fixed as a source and the other is fixed as a drain in some cases. It is needless to say that, depending on a driving method, the magnitude relationship between potentials applied to three terminals of the transistor might be changed, and the source and the drain might be interchanged. Thus, in one embodiment of the present invention, the distinction between the source and drain of the transistor is not limited to that described in this specification and the drawings.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, each of X and Y denotes an object (e.g., a device, an element, a wiring, an electrode, a terminal, a node, a film, a layer, or a region).

Examples of the case where X and Y are directly connected include the case where an element that enables electrical connection between X and Y (e.g., a switch, a transistor, a capacitor, an inductor, a resistor, a diode, a display element, a light-emitting element, or a load) is not connected between X and Y, and the case where X and Y are connected without the element that enables electrical connection between X and Y provided therebetween.

For example, in the case where X and Y are electrically connected, one or more elements that enable electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is conducting or not conducting (is turned on or off) to determine whether current flows therethrough. Alternatively, the switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter (NOT) circuit, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a storage circuit; or a control circuit) can be connected between X and Y. Note that for example, in the case where a signal output from X is transmitted to Y even when another circuit is provided between X and Y, X and Y are functionally connected. The case where X and Y are functionally connected includes the case where X and Y are directly connected and X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the explicit description “X and Y are connected”.

For example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to part of Z1 and another part of Z1 is directly connected to X while a drain (or a second terminal or the like) of the transistor is directly connected to part of Z2 and another part of Z2 is directly connected to Y, can be expressed by using any of the following expressions.

The expressions include, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in that order,” “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in that order,” and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are connected in that order.” When the connection order in a circuit structure is defined by an expression similar to the above examples, a source (or a first terminal or the like) and a drain (or a second terminal or the like) of a transistor can be distinguished from each other to specify the technical scope.

Other examples of the expressions include “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”. It is also possible to use the expression “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film functions as the wiring and the electrode. Thus, the term “electrical connection” in this specification also means such a case where one conductive film has functions of a plurality of components.

In this specification and the like, it might be possible for those skilled in the art to constitute one embodiment of the invention even when portions to which all the terminals of an active element (e.g., a transistor or a diode), a passive element (e.g., a capacitor or a resistor), or the like are connected are not specified. In other words, one embodiment of the invention can be clear even when connection portions are not specified. Furthermore, in the case where a connection portion is disclosed in this specification and the like, it can be determined that one embodiment of the invention in which a connection portion is not specified is disclosed in this specification and the like, in some cases. In particular, in the case where the number of portions to which the terminal is connected might be more than one, it is not necessary to specify the portions to which the terminal is connected. Therefore, it might be possible to constitute one embodiment of the invention by specifying only portions to which some of terminals of an active element (e.g., a transistor or a diode), a passive element (e.g., a capacitor or a resistor), or the like are connected.

In this specification and the like, it might be possible for those skilled in the art to specify the invention when at least the connection portion of a circuit is specified. Alternatively, it might be possible for those skilled in the art to specify the invention when at least the function of a circuit is specified. In other words, one embodiment of the invention is clear when the function of a circuit is specified. Furthermore, it can be determined that one embodiment of the invention in which a function is specified is disclosed in this specification and the like in some cases. Thus, when the connection portion of a circuit is specified, the circuit is disclosed as one embodiment of the invention even if a function is not specified, and one embodiment of the invention can be constituted. Alternatively, when the function of a circuit is specified, the circuit is disclosed as one embodiment of the invention even if a connection portion is not specified, and one embodiment of the invention can be constituted.

One embodiment of the present invention can provide a novel semiconductor device or a method for operating the novel semiconductor device. One embodiment of the present invention can reduce power consumption, for example, reduce power in a resting state. One embodiment of the present invention can shorten time needed to perform processing for transition from a resting state to a normal state or reduce energy needed to perform the processing.

Note that the description of these effects does not disturb the existence of other effects. In one embodiment of the present invention, there is no need to obtain all the effects described above. In one embodiment of the present invention, other objects, effects, and novel features will be apparent from and can be derived from the description of the specification and the drawings.

### BRIEF DESCRIPTION OF DRAWINGS

In the accompanying drawings:

FIGS. 1A and 1B are block diagrams illustrating a structure example of a semiconductor device;

FIGS. 2A to 2D illustrate a power management operation example of a semiconductor device;

FIG. 3 is a flow chart illustrating a power management operation example of a semiconductor device;

FIGS. 4A and 4B are block diagrams illustrating a semiconductor device structure example;

FIG. 5 is a block diagram illustrating a processor core structure example;

FIG. 6 is a circuit diagram illustrating a storage circuit structure example;

FIG. 7 is a timing chart illustrating an operation example of the storage circuit in FIG. 5;

FIG. 8 is a circuit diagram illustrating a cache memory cell structure example;

FIG. 9 is a timing chart illustrating an operation example of the memory cell in FIG. 8;

FIG. 10A is a top view illustrating an OS transistor structure example, FIG. 10B is a cross-sectional view taken along line y1-y2 in FIG. 10A, FIG. 10C is a cross-sectional view taken along line x1-x2 in FIG. 10A, and FIG. 10D is a cross-sectional view taken along line x3-x4 in FIG. 10A;

FIG. 11A is a top view illustrating an OS transistor structure example, FIG. 11B is a cross-sectional view taken along line y1-y2 in FIG. 11A, FIG. 11C is a cross-sectional view taken along line x1-x2 in FIG. 11A, and FIG. 11D is a cross-sectional view taken along line x3-x4 in FIG. 11A;

FIG. 12A is a top view illustrating an OS transistor structure example, FIG. 12B is a cross-sectional view taken along line y1-y2 in FIG. 12A, FIG. 12C is a cross-sectional view taken along line x1-x2 in FIG. 12A, and FIG. 12D is a cross-sectional view taken along line x3-x4 in FIG. 12A;

FIG. 13A is a top view illustrating an OS transistor structure example, FIG. 13B is a cross-sectional view taken along line y1-y2 in FIG. 13A, FIG. 13C is a cross-sectional view taken along line x1-x2 in FIG. 13A, and FIG. 13D is a cross-sectional view taken along line x3-x4 in FIG. 13A;

FIG. 14A is a top view illustrating an OS transistor structure example, FIG. 14B is a cross-sectional view taken along line y1-y2 in FIG. 14A, FIG. 14C is a cross-sectional view taken along line x1-x2 in FIG. 14A, and FIG. 14D is a cross-sectional view taken along line x3-x4 in FIG. 14A;

FIG. 15A is a top view illustrating an OS transistor structure example, FIG. 15B is a cross-sectional view taken along line y1-y2 in FIG. 15A, FIG. 15C is a cross-sectional view taken along line x1-x2 in FIG. 15A, and FIG. 15D is a cross-sectional view taken along line x3-x4 in FIG. 15A;

FIG. 16A is a partial enlarged view of FIG. 11B, and FIG. 16B is an energy band diagram of an OS transistor;

FIG. 17 is a cross-sectional view illustrating a storage device structure example;

FIG. 18A is a flow chart showing a method for manufacturing an electronic component, and FIG. 18B is a schematic perspective view illustrating an electronic component structure example;

FIGS. 19A to 19H illustrate electronic device examples;

FIG. 20 is a micrograph of a fabricated processing unit (chip);

FIGS. 21A to 21C are block diagrams of a processing unit (fabricated chip);

FIGS. 22A to 22C illustrate an SRAM memory cell structure;

FIG. 23 is a block diagram of an SRAM module;

FIG. 24 is a timing chart of an SRAM module;

FIG. 25 is a timing chart of an SRAM module;

FIG. 26 shows evaluation results of the minimum time required for backup and restore in an SRAM;

FIG. 27 shows evaluation results of time required for backup and restore in a flip-flop circuit;

FIG. 28 shows evaluation results of time required for backup and restore in a flip-flop circuit;

FIG. 29 shows relationship between leakage current and a power supply potential of a flip-flop circuit;

FIG. 30 shows processing unit operation using an evaluation program; and

FIGS. 31A, 31B, and 31D show evaluation results of power consumption of a processing unit, and FIG. 31C shows evaluation conditions.

### BEST MODE FOR CARRYING OUT THE INVENTION

Embodiments and an example of the present invention will be described below. Note that one embodiment of the present invention is not limited to the following description. It will be readily appreciated by those skilled in the art that modes and details of the present invention can be modified in various ways without departing from the spirit and scope of the present invention. One embodiment of the present invention therefore should not be construed as being limited to the following description of the embodiments and the example.

In the drawings, the same components, components having similar functions, components formed using the same material, or components formed at the same time are denoted by the same reference numerals, and the description thereof is not repeated in some cases.

In this specification, a clock signal CLK is abbreviated to “a signal CLK,” “CLK,” or the like in some cases. The same applies to other components (e.g., signals, voltages, potentials, circuits, elements, electrodes, and wirings).

Embodiments and an example of the present invention are described below, and any of the embodiments and the example can be combined as appropriate. In addition, in the case where some a plurality of structure examples are given in one embodiment or example, any of the structure examples can be combined as appropriate.

### Embodiment 1

A semiconductor device capable of power gating, a power management unit, and the like are described.

### <Semiconductor Device Structure Example 1>

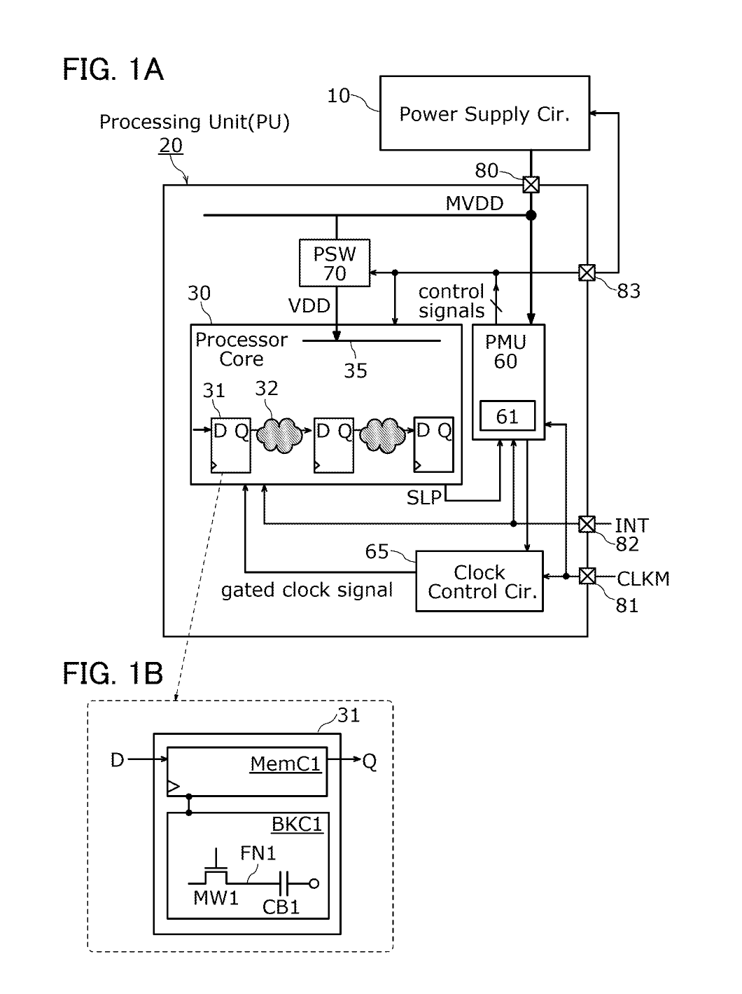

A semiconductor device and power management thereof are described with reference to FIGS. 1A and 1B. The semiconductor device in FIG. 1A includes a power supply circuit 10 and a processing unit (PU) 20. The PU 20 has a function of executing an instruction. The PU 20 includes a plurality of function circuits integrated over one chip. The PU 20 further includes a processor core 30, a power management unit (PMU) 60, a clock control circuit 65, a power switch (PSW) 70, and terminals 80 to 83. FIG. 1A illustrates an example in which the power supply circuit 10 is provided over a chip different from a chip over which the PU 20 is provided. A power supply potential VDD is input from the power supply circuit 10 to the terminal 80. A reference clock signal CLKM is input from the outside to the terminal 81. A signal INT is input from the outside to the terminal 82. The signal NT is an interrupt signal for requesting interrupt processing. The signal NT is input to the PU 20 and the PMU 60. A control signal generated in the PMU 60 is output to the terminal 83, and the terminal 83 is electrically connected to the power supply circuit 10.

### <Processor Core 30, Storage Circuit 31>

The processor core 30 is capable of executing an instruction and can be referred to as an arithmetic processing circuit. The processor core 30 includes a storage circuit 31, a combinational circuit 32, and the like, and a variety of function circuits are formed using these circuits. For example, the storage circuit 31 is included in a register.

As illustrated in FIG. 1B, the storage circuit 31 includes a circuit MemC1 and a circuit BKC1. The circuit MemC1 has a function of retaining data generated in the processor core 30, and can be formed using, a flip-flop circuit (FF) or a latch circuit, for example. The circuit BKC1 can function as a backup circuit of the circuit MemC1, and can retain data for a long time even when power supply is stopped or supply of a clock signal is stopped. The use of the storage circuit 31 enables power gating of the processor core 30. This is because the state of the processor core 30 at the time of power-off can be retained by backing up data of the circuit MemC1 to the circuit BKC1 in the storage circuit 31 before power-off. When the power supply is restarted, data retained in the circuit BKC1 is written to the circuit MemC1; thus, the state of the processor core 30 at the time of power-off can be restored. Consequently, the PU 20 can perform normal processing immediately after the power supply is restarted.

The circuit BKC1 includes at least a retention circuit including one transistor (MW1) and one capacitor (CB1). The retention circuit in FIG. 1B has a circuit configuration similar to a 1T1C (one transistor and one capacitor) memory cell configuration of a standard dynamic random access memory (DRAM), and can perform write and read operations as in the standard DRAM. By controlling conduction of the transistor MW1, charging and discharging of the capacitor CB1 are controlled. When the transistor MW1 is turned off, a node FN1 is set in an electrically floating state. Fluctuation in the potential of the node FN1 can be reduced by significantly reducing the drain current of the transistor MW1 in an off state (off-state current); thus, the data retention period of the circuit BKC1 can be extended. The data retention period of the circuit BKC1 is determined by the leakage current of the transistor MW1, the capacitance of the capacitor CB1, and the like. When the transistor MW1 has extremely low off-state current, refreshing the circuit BKC1 is not needed while a PU 21 operates. Thus, the circuit BKC1 can be used as a nonvolatile storage circuit.

To achieve a transistor with extremely low off-state current, a channel may be formed using a semiconductor having a band gap of greater than or equal to 2.5 eV and a carrier concentration of less than or equal to 1×10¹⁴ cm⁻³. A semiconductor having such characteristics is, for example, an oxide semiconductor. In the OS transistor, normalized off-state current per micrometer of channel width at a source-drain voltage of 10 V can be less than or equal to 10×10⁻²¹ A (10 zA (zeptoampere)). When the transistor MW1 is an OS transistor, the circuit BKC1 can substantially function as a nonvolatile storage circuit while the PU 20 operates. In Embodiment 2, an OS transistor is described.

In the transistor MW1, an oxide semiconductor (OS) layer including a channel may be formed using a single oxide semiconductor film or two or more oxide semiconductor films. An oxide semiconductor included in the OS layer is preferably an oxide semiconductor containing at least one or more elements selected from In, Ga, Sn, and Zn. As such an oxide, an In—Sn—Ga—Zn oxide, an In—Ga—Zn oxide, an In—Sn—Zn oxide, an In—Al—Zn oxide, a Sn—Ga—Zn oxide, an Al—Ga—Zn oxide, a Sn—Al—Zn oxide, an In—Zn oxide, a Sn—Zn oxide, an Al—Zn oxide, a Zn—Mg oxide, a Sn—Mg oxide, an In—Mg oxide, an In—Ga oxide, an In oxide, a Sn oxide, a Zn oxide, or the like can be used. In addition, the oxide may contain an element other than In, Ga, Sn, and Zn, for example, an oxide semiconductor containing SiO₂.

Data is written with voltage in the circuit BKC1; thus, the write power of the circuit BKC1 can be lower than that of a magnetoresistive random access memory (MRAM) in which data is written with current. Furthermore, unlike a flash memory, the number of data rewriting times is not limited because data is retained by the load capacitance of the node FN1.

In the circuit BKC1, energy required for data writing corresponds to energy required for charging and discharging of charge in the capacitor CB1. In contrast, in a storage circuit including a two-terminal memory element such as an MRAM, energy required for data writing corresponds to energy consumed when current flows to the memory element. In the MRAM, energy required for data writing is high because current continuously flows during a data writing period. Compared to such an MRAM, the circuit BKC1 can reduce energy consumed by data writing. Thus, compared to a storage circuit in which a backup circuit is formed using an MRAM, the storage circuit 31 can frequently perform voltage scaling and power gating for reducing consumed energy, which leads to a reduction in the power consumption of the PU 20.

### <Power Management>

The PMU 60 has a function of controlling power gating operation, clock gating operation, voltage scaling operation, and the like. Specifically, the PMU 60 is capable of controlling the power supply circuit 10, capable of controlling the storage circuit 31, capable of controlling the clock control circuit 65, and capable of controlling the PSW 70. Thus, the PMU 60 has a function of generating control signals for controlling the circuits 10, 31, 65, and 70. The PMU 60 includes a circuit 61. The circuit 61 is capable of measuring time. The PMU 60 is capable of performing power management on the basis of data on time obtained by the circuit 61.

The PSW 70 is capable of controlling supply of a power supply potential MVDD to the PU 20 in response to a control signal of the PMU 60. Here, a power supply potential supplied to the PU 20 through the PSW 70 is referred to as the power supply potential VDD. The processor core 30 may include a plurality of power domains. In that case, supply of power to the plurality of power domains may be controlled independently by the PSW 70. In addition, the processor core 30 may include a power domain that does not require power gating. In that case, a power supply potential may be supplied to this power domain without the PSW 70.

The clock control circuit 65 has a function of generating and outputting a gated clock signal by input of the reference clock signal CLKM. The clock control circuit 65 is capable of stopping supply of a clock signal to the processor core 30 in response to a control signal of the PMU 60. The power supply circuit 10 is capable of changing the magnitude of the potential VDD in response to a control signal of the PMU 60.

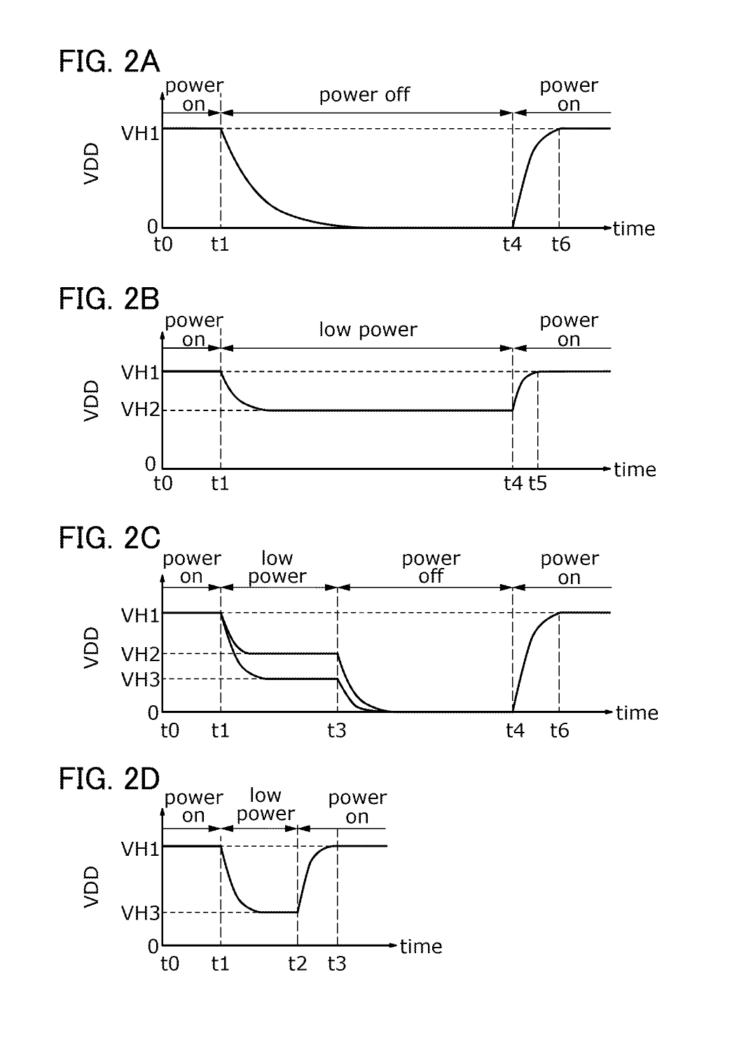

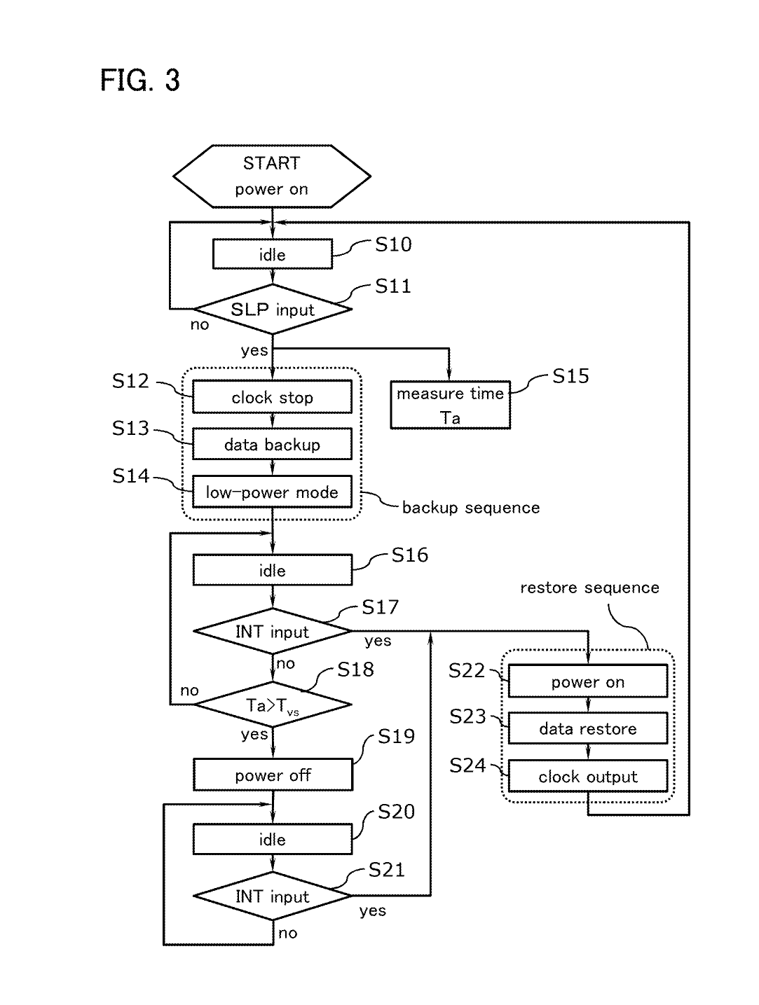

A signal SLP output from the processor core 30 to the PMU 60 is a trigger signal for transferring the processor core 30 to a resting state. When the signal SLP is input to the PMU 60, the PMU 60 generates a control signal for transition to a resting state and outputs the control signal to a function circuit to be controlled. The power supply circuit 10 makes MVDD lower than that in normal operation in response to a control signal of the PMU 60. After the processor core 30 is in the resting state for a certain period of time, the PMU 60 controls the PSW 70 and stops power supply to the processor core 30. When the processor core 30 is transferred from a normal state to the resting state, the PMU 60 performs voltage scaling operation for lowering the power supply potential VDD of the processor core 30. When the period of the resting state exceeds the set time, the PMU 60 performs power gating operation for stopping supply of VDD to the processor core 30 in order to further reduce the power consumption of the processor core 30. Power management of the semiconductor device in FIGS. 1A and 1B is described below with reference to FIGS. 2A to 2D and FIG. 3.

FIGS. 2A to 2D schematically illustrate changes in the potential of a power supply line. The power supply potential VDD is supplied to the power supply line through the PSW 70. The horizontal axis in the graph shows the period elapsing between transition from the normal state to the resting state, and t0, t1, and the like each represent time. FIG. 2A illustrates an example in which only power gating is performed in the resting state. FIG. 2B illustrates an example in which only voltage scaling is performed in the resting state. FIGS. 2C and 2D each illustrate an example in which voltage scaling and power gating are performed. In the normal state, the magnitude of the power supply potential MVDD supplied from the power supply circuit 10 is VH1.

In the following description, the power mode of the PU 20 is divided into three modes: a power-on mode, a power-off mode, and a low-power mode. In the power-on mode, the power supply potential VDD that enables normal processing is supplied to the PU 20. In the power-off mode, the supply of VDD is stopped by the PSW 70. In the low-power mode, the power supply potential VDD lower than that in the power-on mode is supplied.

The example in FIG. 2A is described. At the time t0, processing for transition to the resting state is started in the processor core 30. For example, data of the storage circuit 31 is backed up. The PMU 60 controls the PSW 70 and stops supply of power to the processor core 30 at the time t1. A power supply line 35 is self-discharged and its potential is decreased to 0 V. Consequently, leakage current of the processor core 30 in the resting state can be significantly lowered, so that power consumption in the resting state (hereinafter referred to as standby power in some cases) can be reduced. In the case where the processor core 30 recovers to the normal state in response to an interrupt request or the like from the outside, the PMU 60 controls the PSW 70 and restarts the supply of VDD. Here, at time t4, the supply of VDD is restarted. The potential of the power supply line 35 increases and becomes VH1 at time t6.

In the case of FIG. 2B, voltage scaling is performed; thus, at the time t1, the PMU 60 controls the power supply circuit 10 and lowers the potential of MVDD to VH2. The potential of the power supply line 35 eventually becomes VH2. At the time t4, when the power supply potential MVDD is changed from VH2 to VH1, the potential of the power supply line 35 increases and becomes VH1 at time t5.

In the case of FIG. 2A, time taken to recover the processor core 30 from the resting state to the normal state (overhead time) is time taken to increase the potential of the power supply line 35 from 0 V to VH1, an energy overhead required for recovery is energy required to charge the load capacitance of the power supply line 35 from 0 V to VH1. When the period of the power-off mode (t1 to t4) is sufficiently long, power gating is effective in reducing standby power of the PU 20. In contrast, when the period (t1 to t4) is short, power required to recover the processor core 30 to the normal state is higher than power reduced by power-off; therefore, the effect of power gating cannot be obtained.

In the example of voltage scaling in FIG. 2B, the potential of the power supply line 35 is VH2 in the resting state; thus, the amount of standby power reduction is smaller than that in the example of power gating in FIG. 2A. In the example of FIG. 2B, fluctuation in the potential of the power supply line 35 is small; therefore, time taken to recover the processor core 30 to the normal state is shorter than that in the example of FIG. 2A and energy required to recover the processor core 30 to the normal state is lower than that in the example of FIG. 2A. Accordingly, the semiconductor device in FIGS. 1A and 1B can perform power management in which power gating and voltage scaling are combined to efficiently reduce the standby power of the PU 20. FIGS. 2C and 2D each illustrate a power management example.

As illustrated in FIG. 2C, first, voltage scaling operation is performed in the resting state and the PU 20 is transferred from the power-on mode to the low-power mode. As in FIG. 2B, at the time t1, the PMU 60 controls the power supply circuit 10 and lowers the potential of MVDD to VH2; thus, the potential of the power supply line 35 eventually becomes VH2. After a certain period of time from transition of the PU 20 to the low-power mode (t1 to t3), the PMU 60 controls the PSW 70 and sets the processor core 30 in the power-off mode. In the period (t3 to t4), power reduced by powering off the PU 20 by power gating is higher than power reduced by supplying VH2 to the PU 20 though the power reduced by powering off the PU 20 by power gating include power consumed by recovering the processor core 30 to the normal state.

For example, the potential VH2 is a power supply potential high enough to retain data in the circuit MemC1 of the storage circuit 31, and a potential VH3 is a potential at which data of the circuit MemC1 is lost. In the PU 20 of FIG. 1A, the circuit BKC1 can retain data even while power supply is stopped. If data of the storage circuit 31 is backed up to the circuit BKC1 in the period (t0 to t1), VDD can be lowered to the potential VH3 at which data of the circuit MemC1 is lost in the low-power mode. Thus, the standby power of the PU 20 can be further reduced.

The PMU 60 is capable of recovering the PU 20 to the normal state in response to an interrupt request or the like. The PMU 60 controls the power supply circuit 10 to increase the magnitude of MVDD to VH1 and controls the PSW 70 to restart the supply of VDD from the PU 20. After the time t4, the processor core 30 is in the power-on mode. If the potential of the power supply line 35 is stabilized at the time t6, the PU 20 can perform normal operation after the time t6.

FIG. 2D illustrates an example in which an interrupt request to recover normal operation is input before the time t3. After the time t2, the processor core 30 is in the power-on mode. At the time t2, the PMU 60 controls the power supply circuit 10 to change the magnitude of MVDD to the potential VH1 in the power-on mode. At the time t3, the potential of the power supply line 35 increases to VH1.

As illustrated in FIGS. 2C and 2D, time required to recover the potential of the power supply line 35 to VH1 in the resting state when the processor core 30 recovers from the power-off mode to the power-on mode is longer than time required to recover the potential of the power supply line 35 to VH1 in the resting state when the processor core 30 recovers from the low-power mode to the power-on mode. Thus, the PMU 60 is capable of adjusting timing of recovering the processor core 30 from the resting state to the normal state depending on the power mode. Accordingly, the processor core 30 can recover from the resting state to the normal state in the minimum time.

In the resting state, transition time from the low-power mode to the power-off mode can be measured by the circuit 61 provided in the PMU 60. When the signal SLP is input from the PU 20, the PMU 60 starts to measure time in the circuit 61. After a certain period of time from transition of the PU 20 to the low-power mode, the PMU 60 is transferred to the power-off mode. The PSW 70 is turned off by a control signal of the PMU 60, and the supply of VDD is stopped. In this manner, the PMU 60 can be transferred from the low-power mode to the power-off mode in response to an interrupt request based on measurement data of the circuit 61. A power management operation example of the PMU 60 is described below with reference to FIG. 3.

The PU 20 performs normal operation. The power mode is a power-on mode and the PMU 60 is in an idle state (Step S10). The PMU 60 is in the idle state until the signal SLP is input, and a backup sequence is executed with input of the signal SLP as a trigger (Step S11). In the backup sequence example of FIG. 3, first, the PMU 60 outputs a control signal to the clock control circuit 65 and stops output of a clock signal (Step S12). Next, a control signal for data backup is output to the storage circuit 31 (Step S13). In the storage circuit 31, data retained in the circuit MemC1 is backed up to the circuit BKC1 in response to a control signal of the PMU 60. Finally, the PMU 60 controls the power supply circuit 10 to lower MVDD. Through these operations, the power mode is transferred to the low-power mode. When the signal SLP is input, the PMU 60 controls the circuit 61 and measures time Ta in the low-power mode. Timing of operating the circuit 61 may be any timing as long as the backup sequence is executed. For example, the circuit 61 may operate when the signal SLP is input, when a control signal is output to the clock control circuit 65, when data backup is started, when data backup is terminated, or when a control signal is output to the power supply circuit 10.

After the backup sequence is executed, the PMU 60 is set in an idle state and monitors input of the signal NT and the measurement time Ta of the clock control circuit 65 (Step S16 to Step S18). When the signal INT is input, the sequence is transferred to a restore sequence (Step S17). Then, whether the time Ta exceeds time Tᵥₛ is determined (Step S18). When the time Ta exceeds the time Tᵥₛ, the PMU 60 transfers the power mode to the power-off mode (Step S19). When the time Ta does not exceed the time Tᵥₛ, the PMU 60 remains in the idle state (Step S16). The time Tᵥₛ may be time in which standby power of the processor core 30 in the power-off mode can be lower than standby power of the processor core 30 in the low-power mode.

In Step S19, the PMU 60 outputs a control signal for stopping supply of power to the processor core 30 to the PSW 70. After the mode is transferred to the power-off mode, the PMU 60 is set in an idle state again and input of the signal NT is monitored (Step S20 and Step S21). When the signal NT is input, the PMU 60 executes the restore sequence.

In the restore sequence, first, the PMU 60 is transferred from the power-off mode to the power-on mode (Step S22). The PMU 60 controls the power supply circuit 10 to output a power supply potential in normal operation. In addition, the PMU 60 controls the PSW 70 to restart the supply of VDD to the processor core 30. Next, a control signal is output to the storage circuit 31 and data of the storage circuit 31 is restored (Step S23). In the storage circuit 31, data retained in the circuit BKC1 is restored to the circuit MemC1 in response to a control signal of the PMU 60. The PMU 60 outputs a control signal for outputting a clock signal to the clock control circuit 65 (Step S24). The clock control circuit 65 restarts the output of a clock signal in response to a control signal of the PMU 60.

Compared with the case where the restore sequence is executed in accordance with determination in Step S21, in the case where the restore sequence is executed in accordance with determination in Step S17, the potential of the power supply line 35 can be quickly stabilized because the power mode recovers from the low-power mode to the power-on mode. Thus, in the PMU 60, timing of executing Step S23 when the restore sequence is executed in accordance with Step S17 is faster than that when the restore sequence is executed in accordance with Step S21. Consequently, time taken to recover the processor core 30 from the resting state to the normal state can be shortened.

As described above, in power management of the semiconductor device in FIGS. 1A and 1B, when the PU 20 is set in the resting state, first, time and energy overheads due to recovery from the resting state to the normal state are suppressed while leakage current is reduced by lowering a power supply potential supplied to the processor core 30 with voltage scaling operation. When the PU 20 is in the resting state for a certain period of time, power gating operation is performed to reduce the leakage current of the processor core 30 as much as possible. Thus, the power consumption of the PU 20 in the resting state can be reduced without lowering the processing performance of the PU 20.

### <Semiconductor Device Structure Example 2>

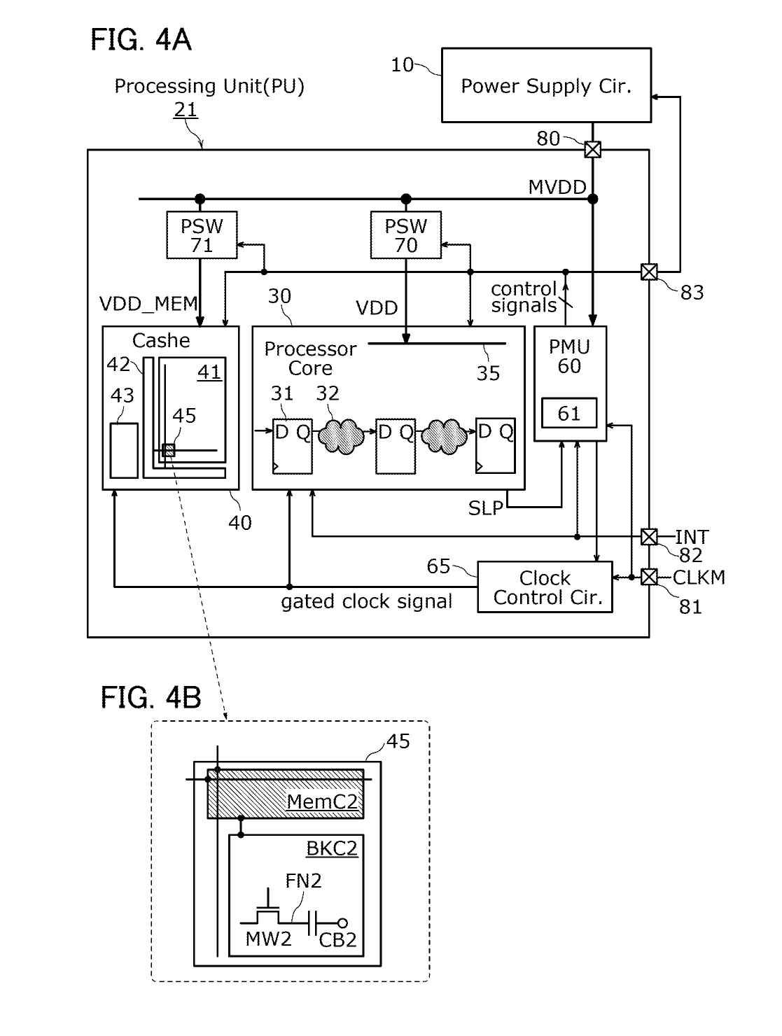

FIG. 4A illustrates a modification example of the semiconductor device in FIG. 1A. The processing unit (PU) 21 in FIG. 4A is obtained by adding a cache 40 and a power switch (PSW) 71 to the PU 20. The cache 40 can perform power gating and voltage scaling as in the PU 20, and the power mode of the cache 40 is changed along with the change in the power mode of the PU 21. The PSW 71 controls supply of the power supply potential MVDD to the cache 40 and is controlled by the PMU 60. Here, a power supply potential input to the cache 40 through the PSW 71 is VDD_MEM. As in the processor core 30, a control signal from the PMU 60 and a gated clock signal from the clock control circuit 65 are input to the cache 40.

### <Cache 40>

The cache 40 is a storage device having a function of temporarily storing frequently used data. The cache 40 includes a memory array 41, a peripheral circuit 42, and a control circuit 43. The memory array 41 includes a plurality of memory cells 45. The control circuit 43 controls operation of the cache 40 in response to a request from the processor core 30. For example, the control circuit 43 controls write and read operations of the memory array 41. The peripheral circuit 42 has a function of generating a signal for driving the memory array 41 in response to a control signal from the control circuit 43. The memory array 41 includes the memory cell 45 for retaining data.

As illustrated in FIG. 4B, the memory cell 45 includes a circuit MemC2 and a circuit BKC2. The circuit MemC2 is a memory cell to be accessed in normal operation. For example, a static random access memory (SRAM) memory cell may be used. The circuit BKC2 can function as a backup circuit of the circuit MemC2, and can retain data for a long time even when power supply is stopped or supply of a clock signal is stopped. When the memory cell 45 is provided, power gating of the cache 40 can be performed. Before the power supply is stopped, data of the circuit MemC2 is backed up to BKC2 in the memory cell 45. After the power supply is restarted, data retained in the circuit BKC2 is restored to the circuit MemC2, so that the PU 21 can quickly recover to the state before the power supply is stopped.

As in the circuit BKC1 of FIG. 1B, the circuit BKC2 in the memory cell 45 includes at least a retention circuit including one transistor (MW2) and one capacitor (CB2). In other words, the circuit BKC2 also includes a retention circuit similar to a 1T1C memory cell of a standard DRAM. The transistor MW2 has extremely low off-state current. As in the transistor MW1, an OS transistor may be used as the transistor MW2. Such a structure can suppress fluctuation in the potential of a node FN2 that is electrically floating also in the circuit BKC2; thus, the circuit BKC2 can retain data for a long time. The data retention period of the circuit BKC2 is determined by the leakage current of the transistor MW2, the capacitance of the capacitor CB2, and the like. When the transistor MW2 has extremely low off-state current, the circuit BKC2 can be used as a nonvolatile storage circuit that does not need refresh operation.

As in the PU 20, in the PU 21 in FIG. 4A, the PMU 60 performs power management (see FIG. 3). In Step S13 in FIG. 3, data backup operation of the storage circuit 31 and the cache 40 is performed. In Step S19, the PSW 70 and the PSW 71 are controlled to stop supply of power to the processor core 30 and the cache 40. In Step S22, the PSW 70 and the PSW 71 are controlled to restart the supply of power to the processor core 30 and the cache 40. In Step S23, data restore operation of the storage circuit 31 and the cache 40 is performed.

Thus, as in the semiconductor device in FIGS. 1A and 1B, the semiconductor device in FIGS. 4A and 4B can reduce power in the resting state of the PU 21 without the decrease in processing capacity of the PU 21 by power management in which voltage scaling and power gating are combined.

### <Processor Core Structure Example>

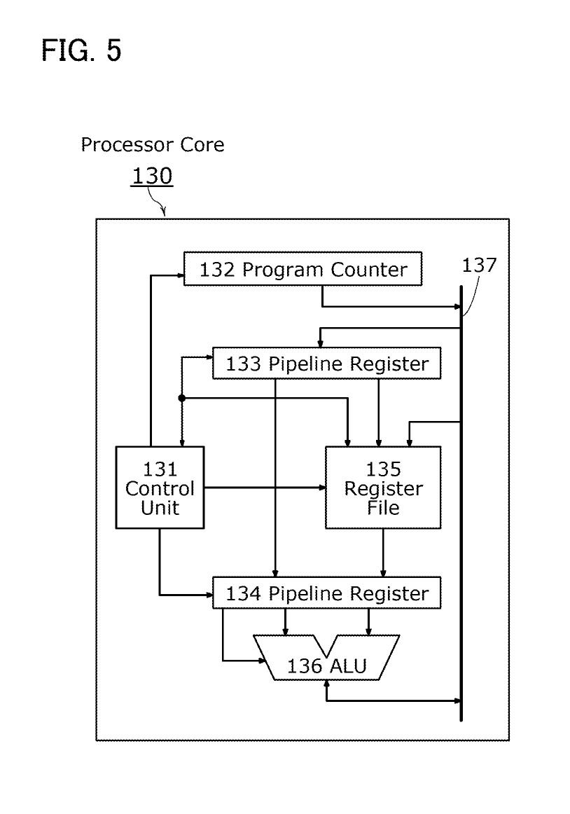

FIG. 5 illustrates a processor core structure example. A processor core 130 in FIG. 5 includes a control unit 131, a program counter 132, a pipeline register 133, a pipeline register 134, a register file 135, an arithmetic logic unit (ALU) 136, and a data bus 137. Data is transmitted between the processor core 130 and a peripheral circuit such as a PMU or a cache through the data bus 137.

The control unit 131 has a function of decoding and executing instructions contained in a program such as input applications by controlling the overall operations of the program counter 132, the pipeline register 133, the pipeline register 134, the register file 135, the ALU 136, and the data bus 137. The ALU 136 has a function of performing a variety of arithmetic operations such as four arithmetic operations and logic operations. The program counter 132 is a register having a function of storing the address of an instruction to be executed next.

The pipeline register 133 has a function of temporarily storing instruction data. The register file 135 includes a plurality of registers including a general-purpose register and can store data read from a main memory, data obtained as a result of arithmetic operations in the ALU 136, or the like. The pipeline register 134 has a function of temporarily storing data used for arithmetic operations performed in the ALU 136, data obtained as a result of arithmetic operations in the ALU 136, or the like.

The storage circuit 31 in FIG. 1B is used as the register included in the processor core 130.

### <Storage Circuit Structure Example>

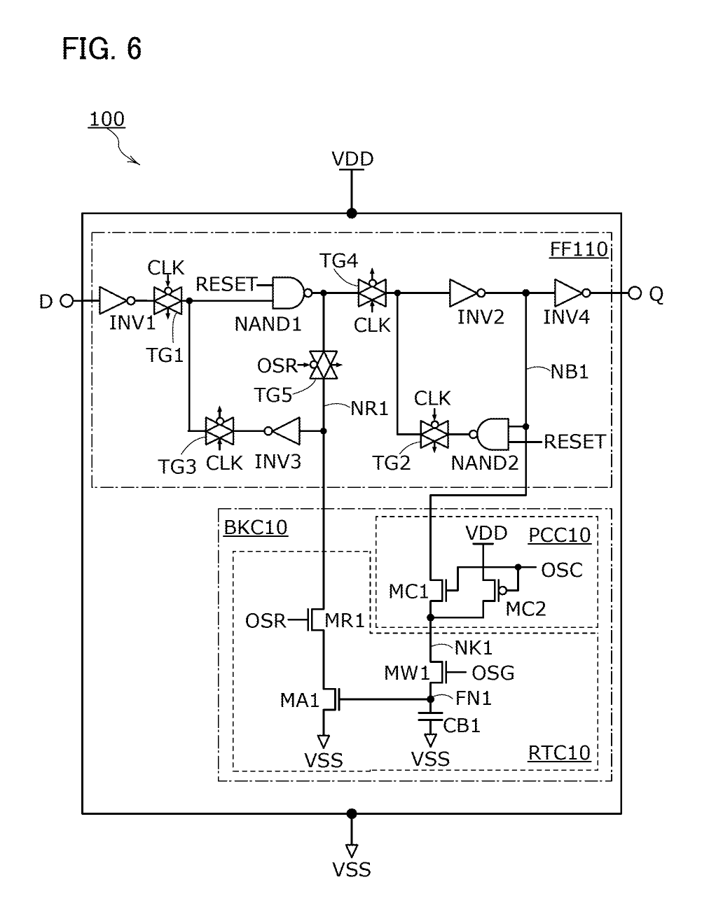

A specific structure example of the storage circuit 31 in FIG. 1B is described. FIG. 6 is a circuit diagram illustrating a storage circuit structure example. A storage circuit 100 in FIG. 6 functions as a flip-flop circuit.

A standard flip-flop circuit (FF), for example, a master slave FF can be used as the circuit MemC1. Such a structure example is illustrated in FIG. 6. An FF 110 includes transmission gates TG1, TG2, TG3, TG4, and TG5, inverter circuits INV1 and INV2, and NAND circuits NAND1 and NAND2. A signal RESET and a signal OSR are control signals output from the PMU 60. The signal OSR and an inverted signal of the signal OSR are input to TG5. The clock signal CLK and an inverted signal of the clock signal CLK are input to TG1 to TG4. One clocked inverter circuit may be provided instead of TG1 and INV1. One clocked NAND circuit may be provided instead of TG2 and NAND2. A clocked inverter circuit may be provided instead of TG3 and INV3. TG5 functions as a switch that controls conduction between an output node of NAND1 and a node NR1. A node NB1 is electrically connected to an input node of a circuit BKC10, and the node NR1 is electrically connected to an output node of the circuit BKC10.

The circuit BKC10 in FIG. 6 functions as a backup circuit of the FF 110. The circuit BKC10 includes a circuit RTC10 and a circuit PCC10. Signals OSG, OSC, and OSR input to the circuit BKC10 are control signals output from the PMU 60. A power supply potential VSS is a low power supply potential and, for example, may be a ground potential GND or 0 V. As in BKC1, the power supply potential VSS and the power supply potential VDD are input to the FF 110. In the storage circuit 100, supply of VDD is controlled by the PMU 60.

The circuit RTC10 includes the transistor MW1, a transistor MAL a transistor MR1, the node FN1, and a node NK1. The circuit RTC10 has a function of data retention, and here, includes a 3T gain-cell storage circuit. The transistor MW1 is a write transistor (OS transistor). The transistor MR1 is a read transistor, and the transistor MA1 functions as an amplifier transistor and a read transistor. The node FN1 retains data. The node NK1 is a data input node. The node NR1 is a data output node of the circuit RTC10.

FIG. 6 illustrates a structure example in which the circuit BKC10 reads data of a slave latch in the FF 110 in backup operation and restores the retained data to a master latch in restore operation. Data to be backed up may be data of the master latch. In addition, data may be restored to the slave latch. In that case, TG5 may be provided in the slave latch.

The transistor MR1 and the transistor MA1 included in the circuit RTC10 may be either n-channel transistors or p-channel transistors, and the level of the potential of the signal OSR and the level of a power supply potential supplied to the transistor MA1 may be changed depending on the conductivity types of the transistor MR1 and the transistor MA1. In addition, a logic circuit of the FF 110 may be set as appropriate. For example, in the case where the transistor MR1 and the transistor MA1 are p-channel transistors, NAND1 and INV3 may be replaced with each other in the master latch and INV2 and NAND2 may be replaced with each other in the slave latch. Furthermore, VDD may be input to the transistor MA1 instead of VSS.

Data is written with voltage in the circuit BKC10; thus, the write power of the circuit BKC10 can be lower than that of an MRAM in which data is written with current. Furthermore, unlike a flash memory, the number of data rewriting times is not limited because data is retained by the load capacitance of the node FN1.

In the circuit RTC10, energy required for data writing corresponds to energy required for charging and discharging of charge in the capacitor CB1. In contrast, in a storage circuit including a two-terminal memory element such as an MRAM, energy required for data writing corresponds to energy consumed when current flows to the memory element. Thus, compared to an MRAM or the like in which current continuously flows during a data writing period, the circuit BKC10 can reduce energy consumed by data backup. Accordingly, compared to the case of providing an MRAM, break even time (BET) can be shortened by providing the circuit BKC10 as a backup circuit. Consequently, opportunities of performing power gating by which consumption energy can be reduced are increased, so that the power consumption of the semiconductor device can be reduced.

The circuit PCC10 includes a transistor MC1 and a transistor MC2. The circuit PCC10 has a function of precharging the node FN1. The circuit PCC10 is not necessarily provided. As described later, the data backup time of the circuit BKC10 can be shortened by providing the circuit PCC10.

### <Operation Example of Storage Circuit>

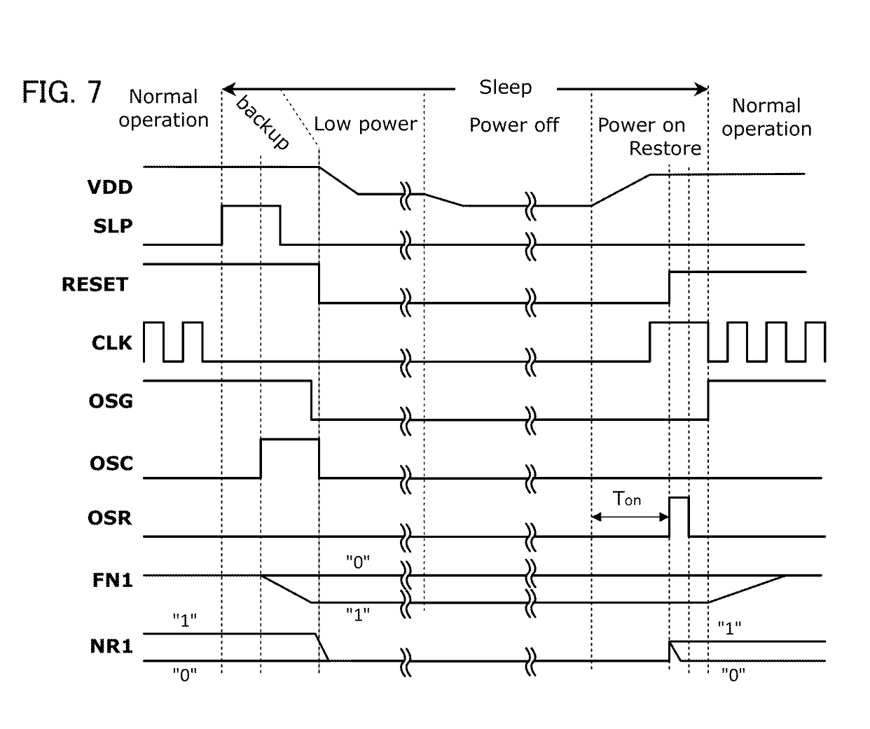

FIG. 7 is a timing chart illustrating an operation example of the storage circuit 100. FIG. 7 illustrates changes in waveforms of control signals SLP, RESET, CLK, OSG, and OSR and changes in the potentials of the power supply potential VDD, the node FN1, and the node NR1.

### [Normal Operation]

The power supply potential VDD and the signal CLK are supplied to the storage circuit 100. The FF 110 functions as a sequential circuit. Since the signal RESET maintains a high level, NAND1 and NAND2 function as inverter circuits. In the circuit BKC1, the transistor MC1 is off and the transistors MC2 and MW1 are on, so that the potential of the node FN1 is precharged to a high level.

### [Data Backup]

First, supply of the clock signal CLK is stopped. Thus, data rewriting of the node NB1 is stopped. In the example of FIG. 7, the potential level of the node NB1 is at a low level (“0”) when the potential of the node NR1 is at a high level (“1”), and the potential level of the node NB1 is at the high level (“1”) when the potential of the node NR1 is at the low level (“0”). While the signal OSC is at a high level, data of the node NB1 is backed up to the node FN1. Specifically, since the transistor MC1 and the transistor MW1 are turned on, the node FN1 is electrically connected to the node NB1. When the signal OSG is set at a low level to turn off the transistor MW1, the node FN1 becomes electrically floating and the circuit BKC10 retains data. The potential of the node FN1 is at a high level when the node NR1 is at the low level (“0”), and the potential of the node FN1 is at a low level when the node NR1 is at the high level (“1”).

Data backup is terminated by setting the signal OSG at a low level. Thus, voltage scaling operation of the PU 20 can be performed immediately after the signal OSG is set at a low level. In addition, since the node FN1 is precharged to the high level by the transistor MC2 in the normal operation, charge transfer of the node FN1 is not needed in data backup operation in which the node FN1 is set at the high level. Thus, the circuit BKC10 can complete backup operation in a short time.

In the data backup operation, the signal CLK may be inactive. Although the potential of the signal CLK is at a low level in the example of FIG. 7, the potential of the signal CLK may be at a high level.

### [Voltage Scaling in Low-Power Mode]

The PMU 60 performs voltage scaling operation along with the signal OSC falling. Thus, the storage circuit 100 is transferred to the low-power mode.

### [Power Gating in Power-Off Mode]

After a certain period of time from transition of the storage circuit 100 to the low-power mode, the PMU 60 performs power gating operation and the storage circuit 100 is transferred to the power-off mode.

### [Power-on Mode]

The PMU 60 recovers the storage circuit 100 to the power-on mode in response to an interrupt request. In the example of FIG. 7, when the potential of a power supply line for supplying VDD is stabilized, the signal CLK is set at a high level.

### [Data Restore]

While the signal OSR is at a high level, data restore operation is performed. When the signal RESET is set at a high level, the potential of the node NR1 is precharged to the high level (“1”). When the signal OSR is set at a high level, TG5 has high impedance and the transistor MR1 is turned on. Conduction of the transistor MA1 is determined by the potential of the node FN1. When the node FN1 is at a high level, the transistor MA1 is on; thus, the potential of the node NR1 is decreased to the low level (“0”). When the node FN1 is at a low level, the potential of the node NR1 is maintained at the high level. In other words, the FF 110 recovers to the state before transition to the resting state.

As described above, rising of the signal RESET and the signal OSR enables restoration of high-level data to the node NR1. Thus, the recovery operation period of the storage circuit 100 can be shortened.

In the example of FIG. 7, the storage circuit 100 is transferred from the power-off mode to the power-on mode. In the case where the storage circuit 100 recovers from the low-power mode to the power-on mode, a period Tₒₙ to stabilization of the potential of the power supply line for supplying VDD is shortened. In that case, rising of the signal OSR may be made faster than that when the storage circuit 100 recovers from the power-off mode.

### [Normal Operation]

By restarting the supply of the signal CLK, the storage circuit 100 recovers to a state in which normal operation can be performed. When the signal OSG is set at a high level, the node FN1 is precharged to a high level by the circuit PCC10.

### <Cache>

An example in which the cache 40 is formed using an SRAM is described.

### <Memory Cell Structure Example>

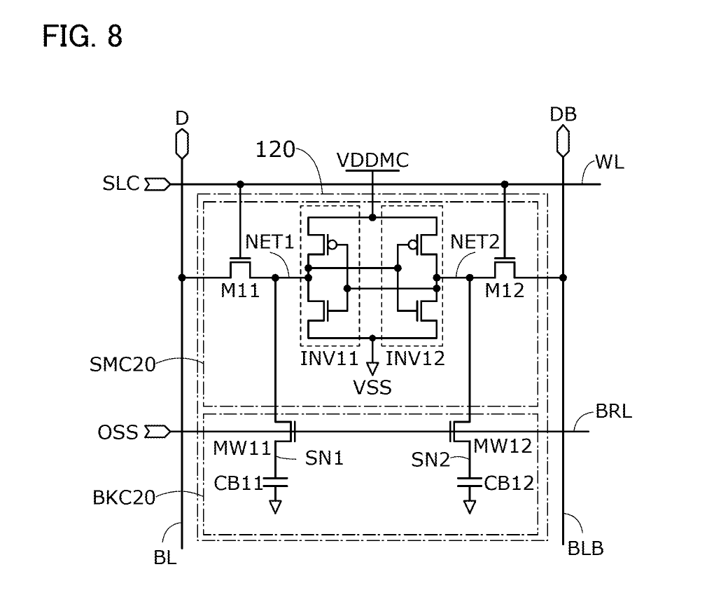

FIG. 8 is a circuit diagram illustrating a cache memory cell structure example. A memory cell 120 in FIG. 8 includes a circuit SMC20 and a circuit BKC20. The circuit SMC20 may have a circuit configuration similar to that of a standard SRAM memory cell. The circuit SMC20 in FIG. 8 includes an inverter circuit INV21, an inverter circuit INV22, a transistor M21, and a transistor M22.

The circuit BKC20 functions as a backup circuit of the circuit SMC20. The circuit BKC20 includes a transistor MW11, a transistor MW12, a capacitor CB11, and a capacitor CB12. The transistors MW11 and MW12 are OS transistors. The circuit SMC20 includes two 1T1C retention circuits, and a node SN1 and a node SN2 each retain data. A retention circuit formed using the transistor MW11 and the capacitor CB11 is capable of backing up data of a node NET1. A retention circuit formed using the transistor MW12 and the capacitor CB12 is capable of backing up data of a node NET2.

Power supply potentials VDDMC and VSS are supplied to the memory cell 120. The memory cell 120 is electrically connected to wirings WL, BL, BLB, and BRL. A signal SLC is input to the wiring WL. A data signal D and a data signal DB are input to the wiring BL and the wiring BLB at the time of data writing. Data is read by detecting the potentials of the wiring BL and the wiring BLB. A signal OSS is input to the wiring BRL. The signal OSS is input from the PMU 60.

### <Memory Cell Operation Example>

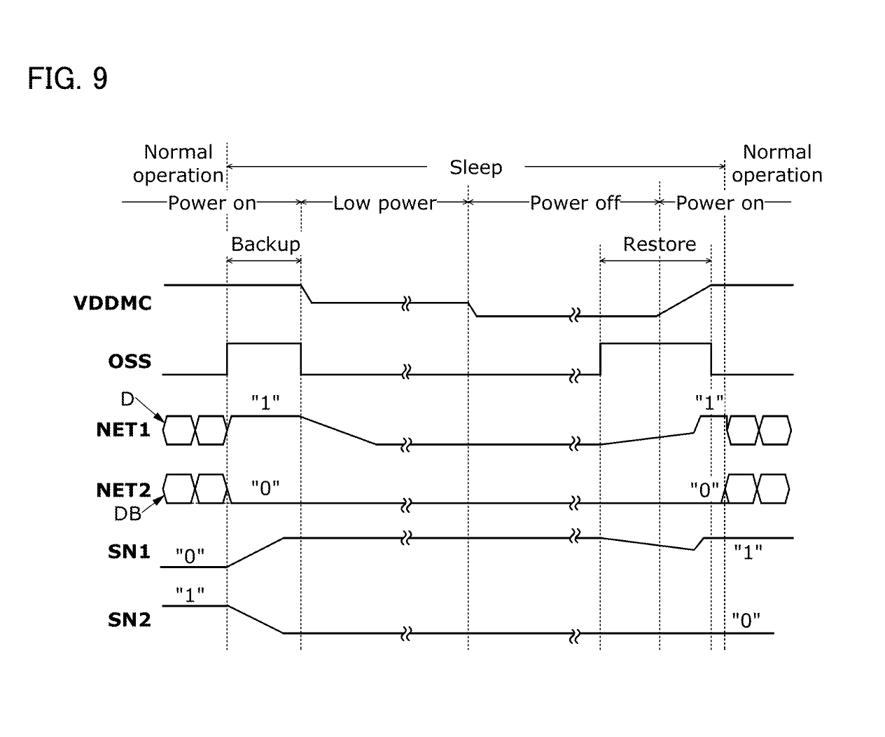

An operation example of the memory cell 120 is described. FIG. 9 is an example of a timing chart of the memory cell 120.

### [Normal Operation]

A request to access a circuit MemC20 is input, and data is written and read. In the circuit BKC20, the signal OSS is at a low level; thus, the node SN1 and the node SN2 are electrically floating and data is retained. In the example of FIG. 9, the potential of the node SN1 is at a low level (“0”) and the potential of the node SN2 is at a high level (“1”).

### [Data Backup]

When the signal OSS is at a high level, the transistors MW11 and MW12 are turned on and the nodes SN1 and SN2 have the same potential levels as the nodes NET1 and NET2. In the example of FIG. 9, the potentials of the nodes SN1 and SN2 are set at a high level and a low level, respectively. The signal OSS is set at a low level and the circuit BKC20 retains data, so that data backup operation is terminated.

### [Voltage Scaling in Low-Power Mode]

The PMU 60 performs voltage scaling operation along with the signal OSS falling. Thus, the cache 40 is transferred to the low-power mode.

### [Power Gating in Power-Off Mode]

After a certain period of time from transition of the cache 40 to the low-power mode, the PMU 60 performs power gating operation and the cache 40 is transferred to the power-off mode.

### [Data Restore in Power-on Mode]

The PMU 60 recovers the cache 40 to a normal state in response to an interrupt request. The signal OSS is set at a high level to restore data retained in the circuit BKC20 to the circuit SMC20. While the signal OSS is at the high level, the PMU 60 performs voltage scaling operation and power gating operation and recovers the storage circuit 100 to the power-on mode. In the example of FIG. 7, when the potential of the power supply line for supplying VDD is stabilized, the signal CLK is set at a high level. When the potential of a power supply line for supplying VDDMC is stabilized, the signal OSS is set at a low level to terminate data restore operation. The nodes SN1 and SN2 recover to states immediately before the resting states.

### [Normal Operation]

When the supply of VDDMC is restarted, the circuit SMC20 recovers to a normal mode in which normal operation can be performed.

As described above, by using an OS transistor, a backup circuit capable of retaining data for a long time even when power supply is stopped can be provided. This backup circuit enables power gating of a processor core and a cache. In addition, in a resting state, when power management in which voltage scaling is combined with power gating is performed, energy and time overheads due to recovery from the resting state to a normal state can be reduced. Thus, power can be reduced efficiently without the decrease in the processing capacity of a processing unit.

### Embodiment 2

In this embodiment, OS transistors are described.

### <OS Transistor Structure Example 1>

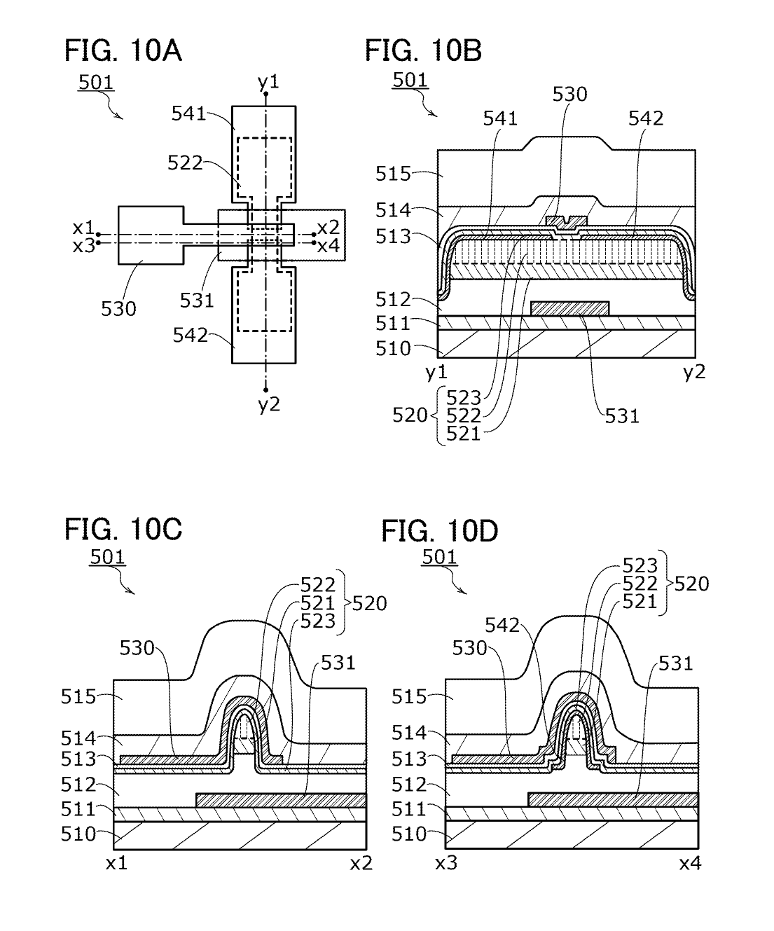

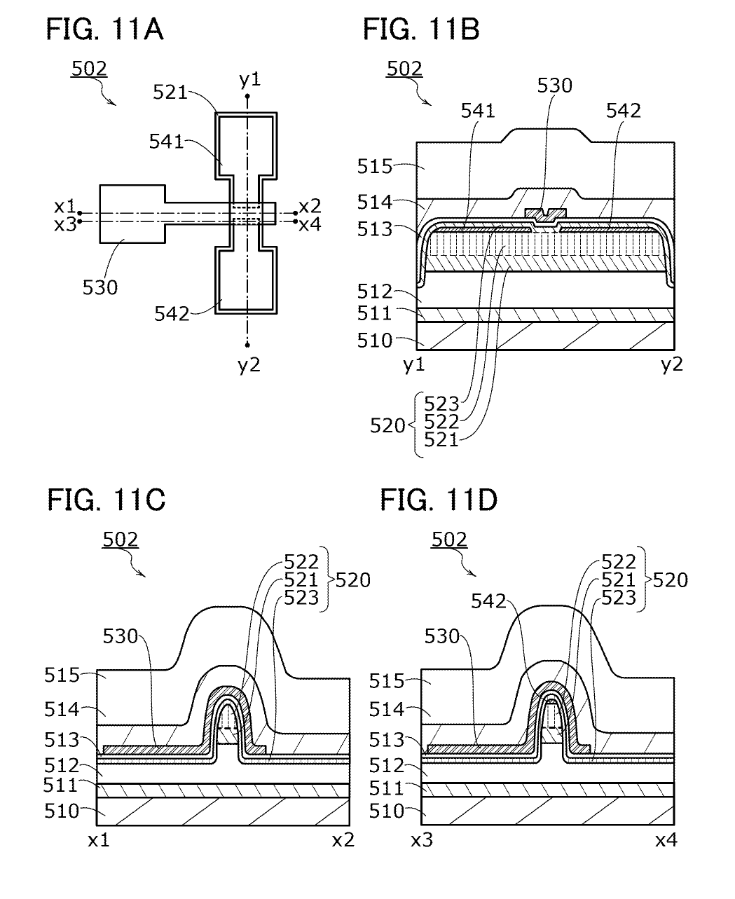

FIGS. 10A to 10D illustrate a structure example of an OS transistor. FIG. 10A is a top view illustrating a structure example of an OS transistor. FIG. 10B is a cross-sectional view taken along line y1-y2 in FIG. 10A. FIG. 10C is a cross-sectional view taken along line x1-x2 in FIG. 10A. FIG. 10D is a cross-sectional view taken along line x3-x4 in FIG. 10A. In some cases, the direction of line y1-y2 is referred to as a channel length direction, and the direction of line x1-x2 is referred to as a channel width direction. Accordingly, FIG. 10B illustrates a cross-sectional structure of the OS transistor in the channel length direction, and FIGS. 10C and 10D each illustrate a cross-sectional structure of the OS transistor in the channel width direction. Note that to clarify the device structure, FIG. 10A does not illustrate some components. The same applies to FIGS. 11A, 12A, 13A, 14A and 15A.

An OS transistor 501 in FIGS. 10A to 10D includes a back gate. The OS transistor 501 is formed over an insulating surface, here, over an insulating layer 511. The insulating layer 511 is formed over a surface of a substrate 510. The OS transistor 501 is covered with an insulating layer 514 and an insulating layer 515. Note that the insulating layers 514 and 515 can be regarded as components of the OS transistor 501. The OS transistor 501 includes an insulating layer 512, an insulating layer 513, oxide semiconductor (OS) layers 521 to 523, a conductive layer 530, a conductive layer 531, a conductive layer 541, and a conductive layer 542. Here, the OS layers 521 to 523 are collectively referred to as an OS layer 520.

The insulating layer 513 includes a region functioning as a gate insulating layer. The conductive layer 530 functions as a gate electrode. The conductive layer 531 functions as a back gate electrode. A constant potential, the same potential or signal supplied to the conductive layer 530, or a potential or signal that is different from that supplied to the conductive layer 530 may be supplied to the conductive layer 531. The conductive layer 541 and the conductive layer 542 function as a source electrode and a drain electrode.

As illustrated in FIGS. 10B to 10C, the OS layer 520 includes a region where the OS layer 521, the OS layer 522, and the OS layer 523 are stacked in that order. The insulating layer 513 covers this stack region. The conductive layer 531 overlaps with the stack region with the insulating layer 513 positioned therebetween. The conductive layer 541 and the conductive layer 542 are provided over the stacked film formed of the OS layer 521 and the OS layer 522 and are in contact with a top surface of this stacked film and a side surface positioned in the channel length direction of the stacked film. In the example of FIGS. 10A to 10D, the conductive layers 541 and 542 are also in contact with the insulating layer 512. The OS layer 523 is formed to cover the OS layers 521 and 522 and the conductive layers 541 and 542. A bottom surface of the OS layer 523 is in contact with a top surface of the OS layer 522.

The conductive layer 530 is formed to surround, in the channel width direction, the region where the OS layers 521 to 523 are stacked in the OS layer 520 with the insulating layer 513 positioned therebetween (see FIG. 10C). Therefore, a gate electric field in a vertical direction and a gate electric field in a lateral direction are applied to this stack region. In the OS transistor 501, the gate electric field refers to an electric field generated by voltage applied to the conductive layer 531 (gate electrode layer). Accordingly, the whole stack region of the OS layers 521 to 523 can be electrically surrounded by the gate electric fields, so that a channel is formed in the whole OS layer 522 (bulk) in some cases. Thus, excellent on-state current characteristics of the OS transistor 501 can be achieved.

In this specification, the structure of a transistor in which a semiconductor is electrically surrounded by a gate electric field as in the above transistor is referred to as a surrounded channel (s-channel) structure. The OS transistor 501 has the s-channel structure. With this s-channel structure, a large amount of current can flow between the source and the drain of the transistor, so that high drain current in an on state (on-state current) can be achieved.

By employing the s-channel structure in the OS transistor 501, channel formation region controllability by a gate electric field applied to the side surface of the OS layer 522 becomes easy. In the structure where the conductive layer 530 reaches below the OS layer 522 and faces the side surface of the OS layer 521, higher controllability can be achieved, which is preferable. Consequently, the subthreshold swing (S value) of the OS transistor 501 can be made small, so that a short-channel effect can be reduced. Thus, the s-channel structure is appropriate for miniaturization.

When an OS transistor has a three-dimensional structure as in the OS transistor 501 in FIGS. 10A to 10D, the channel length can be less than 100 nm. By miniaturization of the OS transistor, circuit area can be made small. The channel length of the OS transistor is preferably less than 65 nm, more preferably less than or equal to 30 nm or less than or equal to 20 nm.

A conductor functioning as a gate of a transistor, a conductor functioning as a source of a transistor, and a conductor functioning as a drain of a transistor are referred to as a gate electrode, a source electrode, and a drain electrode, respectively. A region functioning as a source of a transistor and a region functioning as a drain of a transistor are referred to as a source region and a drain region, respectively. In this specification, a gate electrode might be referred to as a gate, a drain electrode or a drain region might be referred to as a drain, and a source electrode or a source region might be referred to as a source.

The channel length refers to, for example, a distance between a source and a drain in a region where a semiconductor (or a portion where current flows in a semiconductor when a transistor is on) and a gate overlap with each other or in a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where current flows in a semiconductor when a transistor is on) and a gate overlap with each other or a region where a channel is formed. In one transistor, channel widths in all regions do not necessarily have the same value. In other words, the channel width of one transistor is not fixed to one value in some cases. Therefore, in this specification, the channel width is any one of values, the maximum value, the minimum value, or the average value in a region where a channel is formed.

Note that depending on transistor structures, a channel width in a region where a channel is actually formed (hereinafter referred to as an effective channel width) is sometimes different from a channel width shown in a top view of a transistor (hereinafter referred to as an apparent channel width). For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of a semiconductor in some cases. In that case, an effective channel width obtained when a channel is actually formed is greater than an apparent channel width shown in the top view.

In this specification, the term “channel width” may denote an apparent channel width or an effective channel width. Note that the values of a channel length, a channel width, an effective channel width, an apparent channel width, a surrounded channel width, and the like can be determined by obtaining and analyzing a cross-sectional TEM image and the like.

### <OS Transistor Structure Example 2>

An OS transistor 502 in FIGS. 11A to 11D is a modification example of the OS transistor 501. FIG. 11A is a top view of the OS transistor 502. FIG. 11B is a cross-sectional view taken along line y1-y2 in 11A. FIG. 11C is a cross-sectional view taken along line x1-x2 in 11A. FIG. 11D is a cross-sectional view taken along line x3-x4 in 11A.

Like the OS transistor 501, the OS transistor 502 in FIGS. 11A to 11D also has the s-channel structure. The OS transistor 502 does not include the conductive layer 531 and is different from the OS transistor 501 in the shapes of the conductive layer 541 and the conductive layer 542. The conductive layer 541 and the conductive layer 542 in the OS transistor 502 are formed using a hard mask used for forming the stacked film of the OS layer 521 and the OS layer 522. Therefore, the conductive layer 541 and the conductive layer 542 are not in contact with the side surfaces of the OS layer 521 and the OS layer 522 (FIG. 11D).

Through the following steps, the OS layers 521 and 522 and the conductive layers 541 and 542 can be formed. A two-layer oxide semiconductor film including the OS layers 521 and 522 is formed. A single-layer or multi-layer conductive film is formed over the oxide semiconductor film. This conductive film is etched, so that a hard mask is formed. Using this hard mask, the two-layer oxide semiconductor film is etched to form the OS layers 521 and 522. Then, the hard mask is etched to form the conductive layers 541 and 542.

### <OS Transistor Structure Examples 3 and 4>

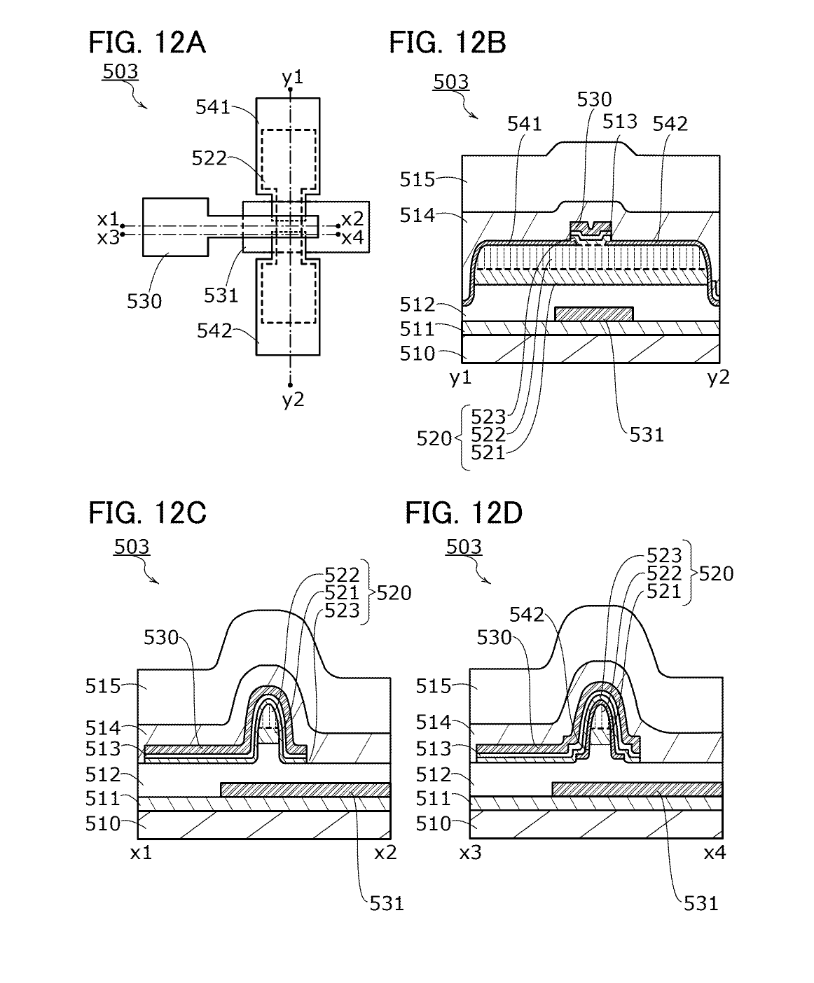

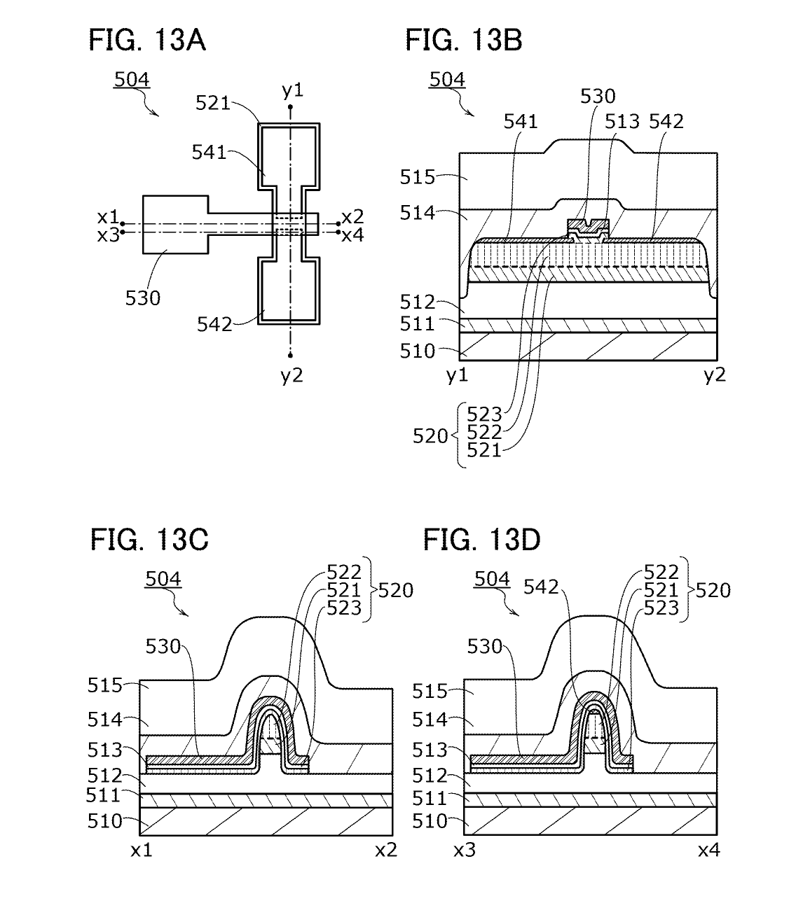

An OS transistor 503 in FIGS. 12A to 12D is a modification example of the OS transistor 501, and an OS transistor 504 in FIGS. 13A to 13D is a modification example of the OS transistor 502. In the OS transistors 503 and 504, the OS layer 523 and the insulating layer 513 are etched using the conductive layer 530 as a mask. Thus, an edge of the OS layer 523 and an edge of the insulating layer 513 are substantially aligned with an edge of the conductive layer 530.

### <OS Transistor Structure Examples 5 and 6>

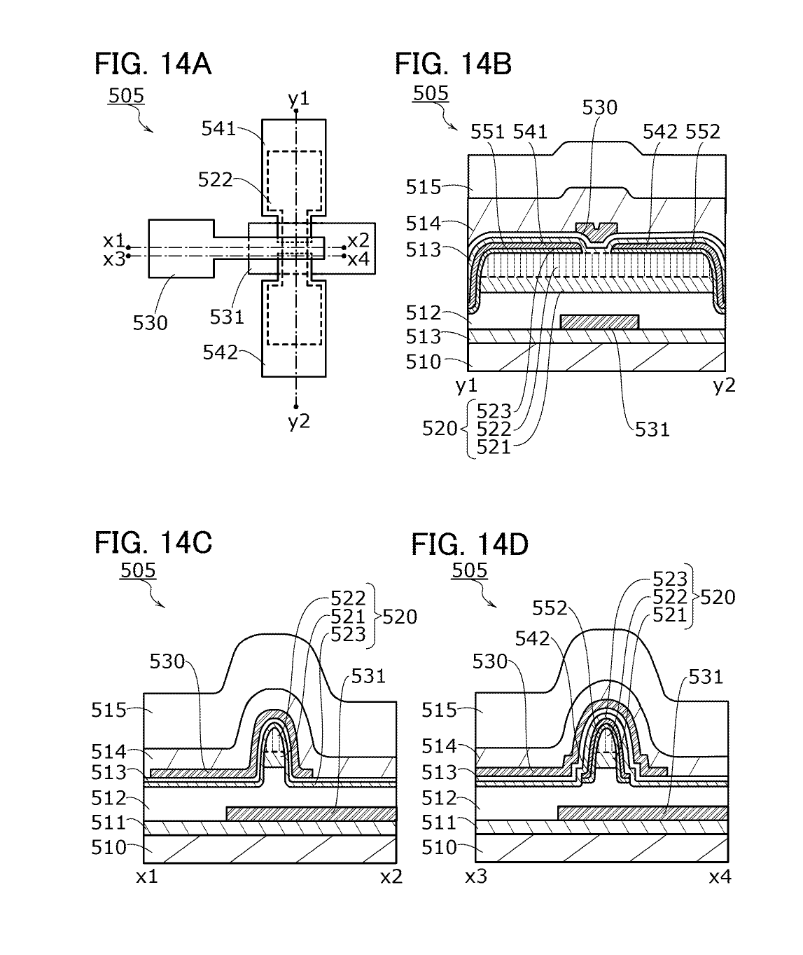

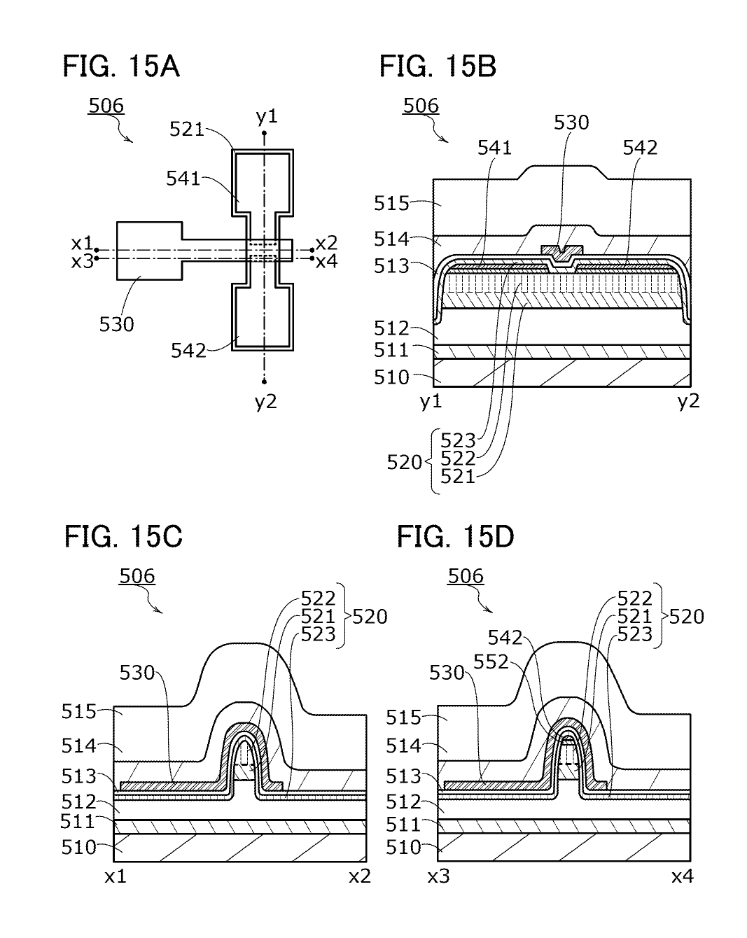

An OS transistor 505 in FIGS. 14A to 14D is a modification example of the OS transistor 501, and an OS transistor 506 in FIGS. 15A to 15D is a modification example of the OS transistor 502. The OS transistors 505 and 506 include a layer 551 between the OS layer 523 and the conductive layer 541 and a layer 552 between the OS layer 523 and the conductive layer 542.

The layers 551 and 552 can be formed using a transparent conductor, an oxide semiconductor, a nitride semiconductor, or an oxynitride semiconductor, for example. The layers 551 and 552 can be formed using an n-type oxide semiconductor layer or can be formed using a conductive layer that has higher resistance than the conductive layers 541 and 542. The layers 551 and 552 may be formed using, for example, a layer containing indium, tin, and oxygen, a layer containing indium and zinc, a layer containing indium, tungsten, and zinc, a layer containing tin and zinc, a layer containing zinc and gallium, a layer containing zinc and aluminum, a layer containing zinc and fluorine, a layer containing zinc and boron, a layer containing tin and antimony, a layer containing tin and fluorine, a layer containing titanium and niobium, or the like. Alternatively, these layers may contain one or more of hydrogen, carbon, nitrogen, silicon, germanium, and argon.

The layers 551 and 552 may have a property of transmitting visible light. Alternatively, the layers 551 and 552 may have a property of not transmitting visible light, ultraviolet light, infrared light, or X-rays by reflecting or absorbing it. In some cases, such a property can suppress a change in electrical characteristics of the transistor due to stray light.

The layers 551 and 552 may preferably be formed using a layer that does not form a Schottky barrier with the OS layer 523. Accordingly, on-state characteristics of the OS transistors 505 and 506 can be improved.

Note that the layers 551 and 552 preferably have higher resistance than the conductive layers 541 and 542. The resistance of the layers 551 and 552 is preferably lower than the channel resistance of the transistor. For example, the layers 551 and 552 may have a resistivity of higher than or equal to 0.1 Ωcm and lower than or equal to 100 Ωcm, higher than or equal to 0.5 Ωcm and lower than or equal to 50 Ωcm, or higher than or equal to 1 Ωcm and lower than or equal to 10 Ωcm. The layers 551 and 552 having resistivity within the above range can reduce electric field concentration in a boundary portion between the channel and the drain. Therefore, a change in electrical characteristics of the transistor can be suppressed. In addition, punch-through current generated by an electric field from the drain can be reduced. Thus, a transistor with small channel length can have favorable saturation characteristics. Note that in a circuit configuration where the source and the drain do not interchange, only one of the layers 551 and 552 (e.g., the layer on the drain side) is preferably provided according to circumstances.

The components of the OS transistors 501 and 502 are described below.

### <Oxide Semiconductor Layer>

As the semiconductor material of the OS layers 521 to 523, typically, an In—Ga oxide, an In—Zn oxide, or an In-M-Zn oxide (M is Ga, Y, Zr, La, Ce, or Nd) is used. In addition, the OS layers 521 to 523 are not limited to the oxide layers containing indium. The OS layers 521 to 523 can be formed using a Zn—Sn oxide layer, a Ga—Sn oxide layer, or a Zn—Mg oxide, for example. The OS layer 522 is preferably formed using an In-M-Zn oxide. The OS layers 521 and 523 can be formed using a Ga oxide.

The case where the OS layers 521 to 523 are formed using an In-M-Zn oxide deposited by sputtering is described. The atomic ratio of metal elements of a target for deposition of an In-M-Zn oxide that is used for forming the OS layer 522 is as follows: In:M:Zn=x₁:y₁:z₁. The atomic ratio of metal elements of a target that is used for forming the OS layers 521 and 523 is as follows: In:M:Zn=x₂:y₂:z₂.

For forming the OS layer 522, a polycrystalline target of an In-M-Zn oxide in which x₁/y₁ is greater than or equal to ⅓ and less than or equal to 6, or greater than or equal to 1 and less than or equal to 6, and z₁/y₁ is greater than or equal to ⅓ and less than or equal to 6, or greater than or equal to 1 and less than or equal to 6 is preferably used. When z₁/y₁ is greater than or equal to 1 and less than or equal to 6, a CAAC-OS film is easily formed. Typical examples of the atomic ratio of the metal elements of the target are In:M:Zn=1:1:1, In:M:Zn=1:1:1.2, In:M:Zn=2:1:1.5, In:M:Zn=2:1:2.3, In:M:Zn=2:1:3, In:M:Zn=3:1:2, and In:M:Zn=4:2:4.1. Note that the CAAC-OS is an oxide semiconductor including a c-axis aligned crystal part, and is described later. Furthermore, it is preferable that the CAAC-OS film have no spinel crystal structure in particular. Using the CAAC-OS film improves reliability and electrical characteristics of the transistor.

In the target used for forming the OS layers 521 and 523, x₂/y₂ is preferably less than x₁/y₁, and z₂/y₂ is preferably greater than or equal to ⅓ and less than or equal to 6, more preferably greater than or equal to 1 and less than or equal to 6. When z₂/y₂ is greater than or equal to 1 and less than or equal to 6, a CAAC-OS film is easily formed. Typical examples of the atomic ratio of the metal elements of the target are In:M:Zn=1:3:2, In:M:Zn=1:3:4, In:M:Zn=1:3:6, In:M:Zn=1:3:8, In:M:Zn=1:4:4, In:M:Zn=1:4:5, In:M:Zn=1:4:6, In:M:Zn=1:4:7, In:M:Zn=1:4:8, In:M:Zn=1:5:5, In:M:Zn=1:5:6, In:M:Zn=1:5:7, In:M:Zn=1:5:8, and In:M:Zn=1:6:8.

Note that in an In-M-Zn oxide film, the proportions of atoms in the atomic ratio vary within a range of ±40% as a margin. For example, the atomic ratio of metal elements contained in an oxide semiconductor film deposited using an oxide target of In:M:Zn=4:2:4.1 is approximately In:M:Zn=4:2:3.

### <Energy Band Structure>

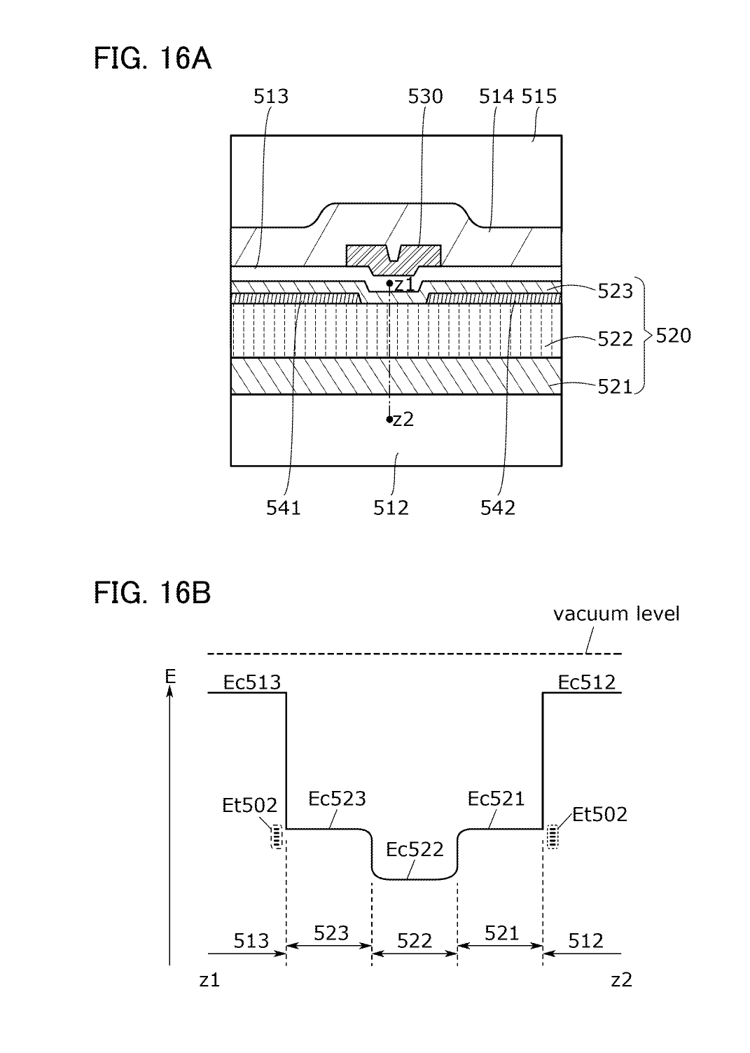

Next, the function and effect of the OS layer 520 in which the OS layers 521, 522, and 523 are stacked are described using an energy band diagram in FIG. 16B. FIG. 16A is an enlarged view of a channel region of the OS transistor 502 in FIG. 11B. FIG. 16B shows an energy band diagram of a portion taken along dotted line z1-z2 (the channel formation region of the OS transistor 502) in FIG. 16A. The OS transistor 502 is described below as an example, but the same applies to the OS transistors 501, 503, 504, 505, and 506.

In FIG. 16B, Ec512, Ec521, Ec522, Ec523, and Ec513 indicate the energy at the bottom of the conduction band of the insulating layer 512, the OS layer 521, the OS layer 522, the OS layer 523, and the insulating layer 513, respectively.

Here, a difference in energy between the vacuum level and the bottom of the conduction band (the difference is also referred to as electron affinity) corresponds to a value obtained by subtracting an energy gap from a difference in energy between the vacuum level and the top of the valence band (the difference is also referred to as an ionization potential). The energy gap can be measured using a spectroscopic ellipsometer (UT-300 manufactured by HORIBA JOBIN YVON S.A.S.). The energy difference between the vacuum level and the top of the valence band can be measured using an ultraviolet photoelectron spectroscopy (UPS) device (VersaProbe manufactured by ULVAC-PHI, Inc.).

Note that an In—Ga—Zn oxide that is formed using a sputtering target having an atomic ratio of In:Ga:Zn=1:3:2 has an energy gap of approximately 3.5 eV and an electron affinity of approximately 4.5 eV. An In—Ga—Zn oxide that is formed using a sputtering target having an atomic ratio of In:Ga:Zn=1:3:4 has an energy gap of approximately 3.4 eV and an electron affinity of approximately 4.5 eV. An In—Ga—Zn oxide that is formed using a sputtering target having an atomic ratio of In:Ga:Zn=1:3:6 has an energy gap of approximately 3.3 eV and an electron affinity of approximately 4.5 eV. An In—Ga—Zn oxide that is formed using a sputtering target having an atomic ratio of In:Ga:Zn=1:6:2 has an energy gap of approximately 3.9 eV and an electron affinity of approximately 4.3 eV. An In—Ga—Zn oxide that is formed using a sputtering target having an atomic ratio of In:Ga:Zn=1:6:8 has an energy gap of approximately 3.5 eV and an electron affinity of approximately 4.4 eV. An In—Ga—Zn oxide that is formed using a sputtering target having an atomic ratio of In:Ga:Zn=1:6:10 has an energy gap of approximately 3.5 eV and an electron affinity of approximately 4.5 eV. An In—Ga—Zn oxide that is formed using a sputtering target having an atomic ratio of In:Ga:Zn=1:1:1 has an energy gap of approximately 3.2 eV and an electron affinity of approximately 4.7 eV. An In—Ga—Zn oxide that is formed using a sputtering target having an atomic ratio of In:Ga:Zn=3:1:2 has an energy gap of approximately 2.8 eV and an electron affinity of approximately 5.0 eV.

Since the insulating layer 512 and the insulating layer 513 are insulators, Ec512 and Ec513 are closer to the vacuum level than Ec521, Ec522, and Ec523 (i.e., the insulating layer 512 and the insulating layer 513 have a lower electron affinity than the OS layers 521, 522, and 523).

Ec521 is closer to the vacuum level than Ec522. Specifically, Ec521 is preferably closer to the vacuum level than Ec522 by 0.05 eV or more, 0.07 eV or more, 0.1 eV or more, or 0.15 eV or more and 2 eV or less, 1 eV or less, 0.5 eV or less, or 0.4 eV or less.

Ec523 is closer to the vacuum level than Ec522. Specifically, Ec523 is preferably closer to the vacuum level than Ec522 by 0.05 eV or more, 0.07 eV or more, 0.1 eV or more, or 0.15 eV or more and 2 eV or less, 1 eV or less, 0.5 eV or less, or 0.4 eV or less.

Mixed regions are formed in the vicinity of the interface between the OS layer 521 and the OS layer 522 and the interface between the OS layer 522 and the OS layer 523; thus, the energy at the bottom of the conduction band changes continuously. In other words, no state or few states exist at these interfaces.

Accordingly, electrons transfer mainly through the OS layer 522 in the layered structure having the energy band structure. Therefore, even if an interface state exists at the interface between the OS layer 521 and the insulating layer 512 or the interface between the OS layer 523 and the insulating layer 513, the interface state hardly influences the transfer of electrons. In addition, since no interface state or few interface states exist at the interface between the OS layer 521 and the OS layer 522 and the interface between the OS layer 523 and the OS layer 522, the transfer of electrons is not interrupted in the region. Consequently, the OS transistor 502 including the stacked oxide semiconductors can have high field-effect mobility.

Although trap states Et502 due to impurities or defects might be formed in the vicinity of the interface between the OS layer 521 and the insulating layer 512 and the interface between the OS layer 523 and the insulating layer 513 as illustrated in FIG. 16B, the OS layer 522 can be separated from the trap states owing to the existence of the OS layers 521 and 523.

In the transistor 502, in the channel width direction, the top surface and side surfaces of the OS layer 522 are in contact with the OS layer 523, and the bottom surface of the OS layer 522 is in contact with the OS layer 521 (see FIG. 11C). Surrounding the OS layer 522 by the OS layers 521 and 523 in this manner can further reduce the influence of the trap states.

However, when the energy difference between Ec522 and Ec521 or Ec523 is small, an electron in the OS layer 522 might reach the trap state by passing over the energy difference. Since the electron is trapped at the trap state, negative fixed charge is generated at the interface with the insulating film, causing the threshold voltage of the transistor to be shifted in a positive direction.

Therefore, each of the energy gaps between Ec521 and Ec522 and between Ec522 and Ec523 is preferably 0.1 eV or more, more preferably 0.15 eV or more because a change in the threshold voltage of the transistor can be reduced and the transistor can have favorable electrical characteristics.

The band gap of each of the OS layers 521 and 523 is preferably wider than that of the OS layer 522.

For the OS layers 521 and 523, a material containing Y, Zr, La, Ce, or Nd with a higher atomic ratio than that used for the OS layer 522 can be used, for example. Specifically, any of the above metal elements with an atomic ratio 1.5 times or more, preferably 2 times or more, more preferably 3 times or more as high as the metal element in the OS layer 522 is contained. Any of the above metal elements is strongly bonded to oxygen and thus has a function of suppressing generation of oxygen vacancy in the oxide semiconductor. That is, oxygen vacancy is less likely to be generated in the OS layers 521 and the 523 than in the OS layer 522.

When the OS layers 521, 522, and 523 are In-M-Zn oxides containing at least indium, zinc, and M (M is Ga, Y, Zr, La, Ce, or Nd) and the atomic ratio of In to M and Zn of the OS layer 521 is x₁:y₁:z₁, that of the OS layer 522 is x₂:y₂:z₂, and that of the OS layer 523 is x₃:y₃:z₃, y₁/x₁ and y₃/x₃ are preferably larger than y₂/x₂. Furthermore, y₁/x₁ and y₃/x₃ are 1.5 times or more as large as y₂/x₂, preferably 2 times or more as large as y₂/x₂, more preferably 3 times or more as large as y₂/x₂. In this case, the transistor can have stable electrical characteristics when y₂ is greater than or equal to x₂ in the OS layer 522. However, when y₂ is 3 times or more as large as x₂, the field-effect mobility of the transistor is reduced; accordingly, y₂ is preferably smaller than 3 times x₂.

An In-M-Zn oxide film satisfying the above conditions can be formed using an In-M-Zn oxide target satisfying the above atomic ratio of metal elements.

In the case where Zn and O are not taken into consideration, the proportion of In and the proportion of M in the OS layer 521 and the OS layer 523 are preferably less than 50 atomic % and greater than 50 atomic %, respectively, more preferably less than 25 atomic % and greater than 75 atomic %, respectively. In the case where Zn and O are not taken into consideration, the proportion of In and the proportion of M in the OS layer 522 are preferably greater than 25 atomic % and less than 75 atomic %, respectively, more preferably greater than 34 atomic % and less than 66 atomic %, respectively.

Note that at least one of the OS layer 521 and the OS layer 523 does not necessarily contain indium in some cases. For example, the OS layer 521 and/or the OS layer 523 can be formed using a gallium oxide film.

The thickness of each of the OS layers 521 and 523 is greater than or equal to 3 nm and less than or equal to 100 nm, preferably greater than or equal to 3 nm and less than or equal to 50 nm. The thickness of the OS layer 522 is greater than or equal to 3 nm and less than or equal to 200 nm, preferably greater than or equal to 3 nm and less than or equal to 100 nm, more preferably greater than or equal to 3 nm and less than or equal to 50 nm. The OS layer 523 is preferably thinner than the OS layers 521 and 522.

Note that in order that an OS transistor in which a channel is formed in an oxide semiconductor have stable electrical characteristics, it is effective to make the oxide semiconductor intrinsic or substantially intrinsic by reducing the concentration of impurities in the oxide semiconductor. The term “substantially intrinsic” refers to a state where an oxide semiconductor has a carrier density lower than 1×10¹⁷/cm³, preferably lower than 1×10¹⁵/cm³, more preferably lower than 1×10¹³/cm³.

In the oxide semiconductor, hydrogen, nitrogen, carbon, silicon, and a metal element other than a main component are impurities. For example, hydrogen and nitrogen form donor levels to increase the carrier density, and silicon forms impurity levels in the oxide semiconductor. The impurity levels serve as traps and might cause the electric characteristics of the transistor to deteriorate. Therefore, it is preferable to reduce the concentration of the impurities in the OS layers 521, 522, and 523 and at interfaces between the OS layers.

In order to make the oxide semiconductor intrinsic or substantially intrinsic, for example, the concentration of silicon at a certain depth of the oxide semiconductor or in a region of the oxide semiconductor, which is measured by SIMS, is lower than 1×10¹⁹ atoms/cm³, preferably lower than 5×10¹⁸ atoms/cm³, more preferably lower than 1×10¹⁸ atoms/cm³. The concentration of hydrogen at a certain depth of the oxide semiconductor or in a region of the oxide semiconductor is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. The concentration of nitrogen at a certain depth of the oxide semiconductor or in a region of the oxide semiconductor is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

In addition, in the case where the oxide semiconductor includes a crystal, high concentration of silicon or carbon might reduce the crystallinity of the oxide semiconductor. In order not to reduce the crystallinity of the oxide semiconductor, for example, the concentration of silicon at a certain depth of the oxide semiconductor or in a region of the oxide semiconductor is lower than 1×10¹⁹ atoms/cm³, preferably lower than 5×10¹⁸ atoms/cm³, more preferably lower than 1×10¹⁸ atoms/cm³. Furthermore, the concentration of carbon at a certain depth of the oxide semiconductor or in a region of the oxide semiconductor is lower than 1×10¹⁹ atoms/cm³, preferably lower than 5×10¹⁸ atoms/cm³, more preferably lower than 1×10¹⁸ atoms/cm³, for example.

A transistor in which the above highly purified oxide semiconductor is used for a channel formation region exhibits extremely low off-state current. When voltage between a source and a drain is set at about 0.1 V, 5 V, or 10 V, for example, the off-state current standardized on the channel width of the transistor can be as low as several yoctoamperes per micrometer to several zeptoamperes per micrometer.

### <Oxide Semiconductor Crystal Structure>

The structure of an oxide semiconductor that forms the OS layer 520 is described.

In this specification, the term “parallel” indicates that the angle formed between two straight lines is greater than or equal to −10° and less than or equal to 10°, and accordingly includes the case where the angle is greater than or equal to −5° and less than or equal to 5°. The term “substantially parallel” indicates that an angle formed between two straight lines is greater than or equal to −30° and less than or equal to 30°. The term “perpendicular” indicates that an angle formed between two straight lines is greater than or equal to 80° and less than or equal to 100°, and accordingly includes the case where the angle is greater than or equal to 85° and less than or equal to 95°. The term “substantially perpendicular” indicates that an angle formed between two straight lines is greater than or equal to 60° and less than or equal to 120°.

In this specification, the trigonal and rhombohedral crystal systems are included in the hexagonal crystal system.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, and microcrystalline oxide semiconductor.

### (CAAC-OS)

A CAAC-OS can be referred to as an oxide semiconductor including c-axis aligned nanocrystals (CANC). The CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of crystal parts can be observed. However, in the high-resolution TEM image, a boundary between crystal parts, that is, a grain boundary is not clearly observed. Thus, in the CAAC-OS, a reduction in electron mobility due to the grain boundary is less likely to occur.

In the high-resolution cross-sectional TEM image of the CAAC-OS observed in a direction substantially parallel to the sample surface, metal atoms arranged in a layered manner are seen in the crystal parts. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

While in the high-resolution planar TEM image of the CAAC-OS observed in a direction substantially perpendicular to the sample surface, metal atoms arranged in a triangular or hexagonal configuration are seen in the crystal parts. However, there is no regularity of arrangement of metal atoms between different crystal parts.

A CAAC-OS analyzed by X-ray diffraction (XRD) is described. When a CAAC-OS including an InGaZnO₄ crystal is subjected to structural analysis by an out-of-plane method, a peak appears frequently when the diffraction angle (2θ) is around 31°. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

In structural analysis of the CAAC-OS by an out-of-plane method, another peak might appear when 2θ is around 36°, in addition to the peak at 2θ of around 31°. The peak of 2θ at around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

The CAAC-OS is an oxide semiconductor having low density of defect states. Defects in the oxide semiconductor are, for example, a defect due to impurity and oxygen vacancies. Therefore, the CAAC-OS can be regarded as an oxide semiconductor with low impurity concentration, or an oxide semiconductor having a small number of oxygen vacancies.

The impurity contained in the oxide semiconductor might serve as a carrier trap or serve as a carrier generation source. Furthermore, oxygen vacancies in the oxide semiconductor serve as carrier traps or serve as carrier generation sources when hydrogen is captured therein. Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of atomic arrangement and lower crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

An oxide semiconductor having low density of defect states (a small number of oxygen vacancies) can have low carrier density. Such an oxide semiconductor is referred to as a highly purified intrinsic or substantially highly purified intrinsic oxide semiconductor. A CAAC-OS has low impurity concentration and low density of defect states. That is, a CAAC-OS is likely to be a highly purified intrinsic or substantially highly purified intrinsic oxide semiconductor. Thus, a transistor including a CAAC-OS rarely has negative threshold voltage (is rarely normally on). The highly purified intrinsic or substantially highly purified intrinsic oxide semiconductor has few carrier traps. Charge trapped by the carrier traps in the oxide semiconductor takes a long time to be released. The trapped charge may behave like fixed charge. Thus, the transistor that includes the oxide semiconductor having high impurity concentration and high density of defect states might have unstable electrical characteristics. However, the transistor including the CAAC-OS has small variation in electrical characteristics and high reliability.

Since the CAAC-OS has low density of defect states, carriers generated by light irradiation or the like are less likely to be trapped in defect states. Therefore, in a transistor using the CAAC-OS, change in electrical characteristics due to irradiation with visible light or ultraviolet light is small.

### (Microcrystalline Oxide Semiconductor)

A microcrystalline oxide semiconductor has a region in which a crystal part is observed and a region in which a crystal part is not observed clearly in a high-resolution TEM image. In most cases, a crystal part in the microcrystalline oxide semiconductor is greater than or equal to 1 nm and less than or equal to 100 nm, or greater than or equal to 1 nm and less than or equal to 10 nm. A microcrystal with a size greater than or equal to 1 nm and less than or equal to 10 nm, or a size greater than or equal to 1 nm and less than or equal to 3 nm is specifically referred to as nanocrystal (nc). An oxide semiconductor including nanocrystal is referred to as a nanocrystalline oxide semiconductor (nc-OS). In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (e.g., a region with a size greater than or equal to 1 nm and less than or equal to 10 nm, in particular, a region with a size greater than or equal to 1 nm and less than or equal to 3 nm) has periodic atomic arrangement. There is no regularity of crystal orientation between different crystal parts in the nc-OS. Thus, the orientation of the film is not observed. Accordingly, in some cases, the nc-OS cannot be distinguished from an amorphous oxide semiconductor depending on an analysis method. For example, when the nc-OS is subjected to structural analysis by an out-of-plane method with XRD using an X-ray beam having a diameter larger than that of a crystal part, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a crystal part (the electron diffraction is also referred to as selected-area electron diffraction). Meanwhile, spots appear in a nanobeam electron diffraction pattern of the nc-OS when an electron beam having a probe diameter close to or smaller than the size of a crystal part is applied. Moreover, in a nanobeam electron diffraction pattern of the nc-OS, regions with high luminance in a circular (ring) pattern are shown in some cases. A plurality of spots are shown in a ring-like region in some cases.

Since there is no regularity of crystal orientation between the pellets (nanocrystals) as described above, the nc-OS can also be referred to as an oxide semiconductor including random aligned nanocrystals (RANC) or an oxide semiconductor including non-aligned nanocrystals (NANC).

The nc-OS is an oxide semiconductor that has higher regularity than an amorphous oxide semiconductor. Therefore, the nc-OS is likely to have lower density of defect states than an amorphous oxide semiconductor. Note that there is no regularity of crystal orientation between different crystal parts in the nc-OS. Therefore, the nc-OS has higher density of defect states than the CAAC-OS.

### (Amorphous Oxide Semiconductor)

The amorphous oxide semiconductor is an oxide semiconductor having disordered atomic arrangement and no crystal part. For example, the amorphous oxide semiconductor does not have a specific state as in quartz.

In a high-resolution TEM image of the amorphous oxide semiconductor, crystal parts cannot be found. When the amorphous oxide semiconductor is subjected to structural analysis by an out-of-plane method with XRD, a peak which shows a crystal plane does not appear. A halo pattern is observed when the amorphous oxide semiconductor is subjected to electron diffraction. Furthermore, a spot is not observed and a halo pattern appears when the amorphous oxide semiconductor is subjected to nanobeam electron diffraction.

There are various understandings of an amorphous structure. For example, a structure whose atomic arrangement does not have ordering at all is called a completely amorphous structure. Meanwhile, a structure which has ordering until the nearest neighbor atomic distance or the second-nearest neighbor atomic distance but does not have long-range ordering is also called an amorphous structure. Therefore, the strictest definition does not permit an oxide semiconductor to be called an amorphous oxide semiconductor as long as even a negligible degree of ordering is present in atomic arrangement. At least an oxide semiconductor having long-term ordering cannot be called an amorphous oxide semiconductor. Accordingly, because of the presence of a crystal part, for example, a CAAC-OS and an nc-OS cannot be called an amorphous oxide semiconductor or a completely amorphous oxide semiconductor.

### <Amorphous-Like Oxide Semiconductor>

An oxide semiconductor may have a structure intermediate between the nc-OS and the amorphous oxide semiconductor. The oxide semiconductor having such a structure is specifically referred to as an amorphous-like oxide semiconductor (a-like OS).

In a high-resolution TEM image of the a-like OS, a void is observed in some cases. Furthermore, in the high-resolution TEM image, there are a region where a crystal part is clearly observed and a region where a crystal part is not observed. The a-like OS has an unstable structure because it contains a void. Thus, growth of the crystal part in the a-like OS is induced by electron irradiation in some cases. In contrast, in the nc-OS and the CAAC-OS, growth of the crystal part is hardly induced by electron irradiation. Therefore, the a-like OS has an unstable structure as compared with the nc-OS and the CAAC-OS.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Accordingly, the spacing between these adjacent layers is equivalent to the lattice spacing on the (009) plane (also referred to as d value). The value is calculated to be 0.29 nm from crystal structure analysis. Thus, each of the lattice fringes in which the spacing therebetween is from 0.28 nm to 0.30 nm corresponds to the a-b plane of the InGaZnO₄ crystal, focusing on the lattice fringes in the high-resolution TEM image.

The a-like OS has lower density than the nc-OS and the CAAC-OS because it contains a void. Specifically, the density of the a-like OS is higher than or equal to 78.6% and lower than 92.3% of the density of a single crystal oxide semiconductor having the same composition. The density of each of the nc-OS and the CAAC-OS is higher than or equal to 92.3% and lower than 100% of the density of a single crystal oxide semiconductor having the same composition. Note that it is difficult to deposit an oxide semiconductor having a density of lower than 78% of the density of a single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that single crystals with the same composition do not exist in some cases. In that case, by combining single crystals with different compositions at a given proportion, it is possible to calculate density that corresponds to the density of a single crystal with a desired composition. The density of the single crystal with a desired composition may be calculated using weighted average with respect to the combination ratio of the single crystals with different compositions. Note that it is preferable to combine as few kinds of single crystals as possible for density calculation.

As described above, oxide semiconductors have various structures and various properties. The oxide semiconductor may be a stacked film including two or more of an amorphous oxide semiconductor, an a-like OS, a microcrystalline oxide semiconductor, and a CAAC-OS, for example.

### <Substrate>

The substrate 510 is not limited to a simple supporting substrate and may be a substrate where a device such as a transistor is formed. In that case, one of the conductive layers 530, 541, and 542 of the OS transistor 501 may be electrically connected to the device.

### <Base Insulating Film>

The insulating layer 511 has a function of preventing impurity diffusion from the substrate 510. The insulating layer 512 preferably has a function of supplying oxygen to the OS layer 520. For this reason, the insulating layer 512 is preferably an insulating film containing oxygen, more preferably, an insulating film containing oxygen in which the oxygen content is higher than that in the stoichiometric composition. For example, a film from which oxygen molecules at more than or equal to 1.0×10¹⁸ molecules/cm³ are released in thermal desorption spectroscopy (TDS) at a surface temperature of the film of higher than or equal to 100° C. and lower than or equal to 700° C., or higher than or equal to 100° C. and lower than or equal to 500° C. can be used. When the substrate 510 is a substrate where a device is formed as described above, the insulating layer 511 is preferably subjected to planarization treatment such as chemical mechanical polishing (CMP) so as to have a flat surface.

The insulating layers 511 and 512 can be formed using an insulating material of aluminum oxide, aluminum oxynitride, magnesium oxide, silicon oxide, silicon oxynitride, silicon nitride oxide, gallium oxide, germanium oxide, yttrium oxide, zirconium oxide, lanthanum oxide, neodymium oxide, hafnium oxide, tantalum oxide, silicon nitride, silicon nitride oxide, aluminum nitride oxide, or the like, or a mixed material of these materials. In this specification, oxynitride refers to a material which includes more oxygen than nitrogen, and nitride oxide refers to a substance which includes more nitrogen than oxygen.

### <Gate Electrode>

The conductive layer 530 is preferably formed using a single low-resistant material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), cobalt (Co), ruthenium (Ru), iridium (Ir), strontium (Sr), and platinum (Pt); an alloy of any of these materials; or a compound containing any of these materials as its main component.

The conductive layer 530 may have a single-layer structure or a layered structure of two or more layers. For example, any of the following structures can be employed: a single-layer structure of an aluminum film containing silicon; a two-layer structure in which a titanium film is stacked over an aluminum film; a two-layer structure in which a titanium film is stacked over a titanium nitride film; a two-layer structure in which a tungsten film is stacked over a titanium nitride film; a two-layer structure in which a tungsten film is stacked over a tantalum nitride film or a tungsten nitride film; a three-layer structure in which a titanium film, an aluminum film, and a titanium film are stacked in this order; a single-layer structure of a Cu—Mn alloy film; a two-layer structure in which a Cu film is stacked over a Cu—Mn alloy film; and a three-layer structure in which a Cu—Mn alloy film, a Cu film, and a Cu—Mn alloy film are stacked in this order. A Cu—Mn alloy film is preferably used because of its low electrical resistance and because it forms manganese oxide at the interface with an insulating film containing oxygen and manganese oxide can prevent Cu diffusion.

The conductive layer 530 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a layered structure formed using the above light-transmitting conductive material and the above metal element.

### <Gate Insulating Layer>

The insulating layer 513 is formed using an insulating film having a single-layer structure or a layered structure. The insulating layer 513 can be formed using an insulating film containing at least one of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. The insulating layer 513 may be a stack including any of the above materials. The insulating layer 513 may contain lanthanum (La), nitrogen, zirconium (Zr), or the like as an impurity. The insulating layer 511 can be formed in a manner similar to that of the insulating layer 513. The insulating layer 513 contains oxygen, nitrogen, silicon, hafnium, or the like, for example. Specifically, the insulating layer 513 preferably contains hafnium oxide, and silicon oxide or silicon oxynitride.

Hafnium oxide has a higher dielectric constant than silicon oxide and silicon oxynitride. Therefore, the insulating layer 513 using hafnium oxide can have larger thickness than the insulating layer 513 using silicon oxide, so that leakage current due to tunnel current can be reduced. That is, a transistor with low off-state current can be provided. Moreover, hafnium oxide with a crystal structure has a higher dielectric constant than hafnium oxide with an amorphous structure. Therefore, it is preferable to use hafnium oxide with a crystal structure in order to provide a transistor with low off-state current. Examples of the crystal structure include a monoclinic crystal structure and a cubic crystal structure. Note that one embodiment of the present invention is not limited to the above examples.

### <Source Electrode, Drain Electrode, Back Gate Electrode>

The conductive layers 541 and 542 and the conductive layer 531 can be formed in a manner similar to that of the conductive layer 530. A Cu—Mn alloy film is preferably used for the conductive layers 541 and 542 because of its low electrical resistance and because it forms manganese oxide at the interface with the OS layer 520 and manganese oxide can prevent Cu diffusion.

### <Protective Insulating Film>

The insulating layer 514 preferably has a function of blocking oxygen, hydrogen, water, an alkali metal, an alkaline earth metal, and the like. The insulating layer 514 can prevent outward diffusion of oxygen from the OS layer 520 and entry of hydrogen, water, or the like into the OS layer 520 from the outside. The insulating layer 514 can be a nitride insulating film, for example. The nitride insulating film is formed using silicon nitride, silicon nitride oxide, aluminum nitride, aluminum nitride oxide, or the like. Note that instead of the nitride insulating film having a blocking effect against oxygen, hydrogen, water, an alkali metal, an alkaline earth metal, and the like, an oxide insulating film having a blocking effect against oxygen, hydrogen, water, and the like may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be used.

An aluminum oxide film is preferably used as the insulating layer 514 because it is highly effective in preventing transmission of both oxygen and impurities such as hydrogen and moisture. Thus, during and after the manufacturing process of the transistor, the aluminum oxide film can suitably function as a protective film that has effects of preventing entry of impurities such as hydrogen and moisture, which cause variations in the electrical characteristics of the transistor, into the OS layer 520, preventing release of oxygen, which is the main component of the OS layer 520, from the oxide semiconductor, and preventing unnecessary release of oxygen from the insulating layer 512. In addition, oxygen contained in the aluminum oxide film can be diffused into the oxide semiconductor.

### <Interlayer Insulating Film>

The insulating layer 515 is preferably formed over the insulating layer 514. The insulating layer 515 can be formed using an insulating film with a single-layer structure or a layered structure. The insulating layer can be formed using an insulating film containing one or more of magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

### <Deposition Method>

Sputtering and plasma-enhanced CVD are typical examples of a method for depositing an insulating film, a conductive film, a semiconductor film, and the like included in a semiconductor device. The insulating film, the conductive film, the semiconductor film, and the like may be formed by another method, for example, thermal CVD. Metal organic chemical vapor deposition (MOCVD) or atomic layer deposition (ALD) can be employed as thermal CVD, for example.

Thermal CVD does not generate plasma and thus has an advantage that no defect due to plasma damage is caused. Deposition by thermal CVD may be performed in such a manner that the pressure in a chamber is set to an atmospheric pressure or a reduced pressure, and a source gas and an oxidizer are supplied to the chamber at the same time and react with each other in the vicinity of the substrate or over the substrate.

Deposition by ALD may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). In such a case, a first source gas is introduced, an inert gas (e.g., argon or nitrogen) or the like is introduced at the same time as or after the introduction of the first gas so that the source gases are not mixed, and then a second source gas is introduced. Note that in the case where the first source gas and the inert gas are introduced at the same time, the inert gas serves as a carrier gas, and the inert gas may also be introduced at the same time as the introduction of the second source gas. Alternatively, the first source gas may be exhausted by vacuum evacuation instead of the introduction of the inert gas, and then the second source gas may be introduced. The first source gas is adsorbed on the surface of the substrate to form a first single-atomic layer; then the second source gas is introduced to react with the first single-atomic layer; as a result, a second single-atomic layer is stacked over the first single-atomic layer, so that a thin film is formed. The sequence of the gas introduction is repeated more than once until desired thickness is obtained, so that a thin film with excellent step coverage can be formed. The thickness of the thin film can be adjusted by the number of repetition times of the sequence of the gas introduction; therefore, ALD makes it possible to accurately adjust thickness and thus is suitable for manufacturing a minute FET.

The conductive film and the semiconductor film that are described in the above embodiment can be formed by thermal CVD such as MOCVD or ALD. For example, in the case where an InGaZnO_{X} (X>0) film is formed, trimethylindium, trimethylgallium, and dimethylzinc are used. Note that the chemical formula of trimethylindium is (CH₃)₃In. The chemical formula of trimethylgallium is (CH₃)₃Ga. The chemical formula of dimethylzinc is (CH₃)₂Zn. Without limitation to the above combination, triethylgallium (chemical formula: (C₂H₅)₃Ga) can be used instead of trimethylgallium and diethylzinc (chemical formula: (C₂H₅)₂Zn) can be used instead of dimethylzinc.

For example, in the case where a tungsten film is formed using a deposition apparatus employing ALD, a WF₆ gas and a B₂H₆ gas are sequentially introduced more than once to form an initial tungsten film, and then a WF₆ gas and an H₂ gas are used, so that a tungsten film is formed. Note that an SiH₄ gas may be used instead of a B₂H₆ gas.

For example, in the case where an oxide semiconductor film, e.g., an InGaZnO_{X} (X>0) film is formed using a deposition apparatus employing ALD, a (CH₃)₃In gas and an O₃ gas are sequentially introduced more than once to form an InO₂ layer, a (CH₃)₃Ga gas and an O₃ gas are used to form a GaO layer, and then a (CH₃)₂Zn gas and an O₃ gas are used to form a ZnO layer. Note that the order of these layers is not limited to this example. A mixed compound layer such as an InGaO₂ layer, an InZnO₂ layer, a GaInO layer, a ZnInO layer, or a GaZnO layer may be formed by mixing these gases. Note that although an H₂O gas that is obtained by bubbling with an inert gas such as Ar may be used instead of an O₃ gas, it is preferable to use an O₃ gas, which does not contain H. Instead of a (CH₃)₃In gas, a (C₂H₅)₃In gas may be used. Instead of a (CH₃)₃Ga gas, a (C₂H₅)₃Ga gas may be used. Furthermore, a (CH₃)₂Zn gas may be used.

### Embodiment 3

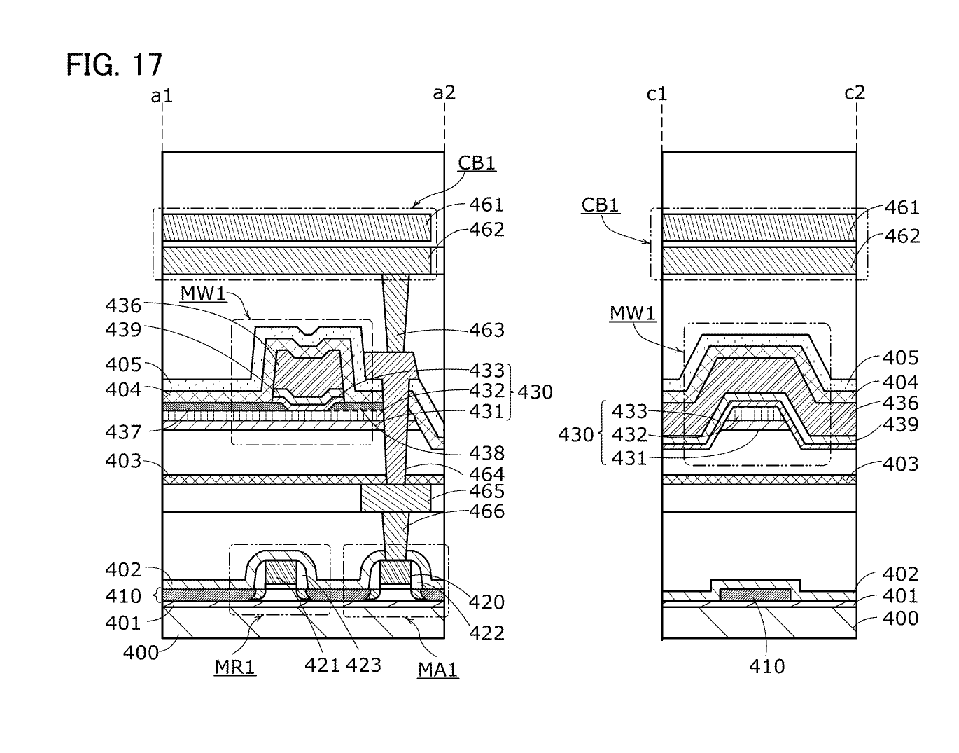

In this embodiment, the device structure of a semiconductor device is described. As described in Embodiment 1, the semiconductor device can include a Si transistor and an OS transistor. In such a structure example, the semiconductor device can be downsized by stacking the Si transistor and the OS transistor. A structure example of a semiconductor device with such a layered structure is described with reference to FIG. 17.

Here, a device structure of the PU 21 in FIG. 4A is described as an example of the semiconductor device. FIG. 17 typically illustrates the transistor MW1, the transistor MA1, the transistor MR1, and the capacitor CB1 in the circuit RTC10. A cross-sectional view taken along line a1-a2 illustrates the cross-sectional structure of the transistors MW1 and MA2 in a channel length direction. A cross-sectional view taken along line c1-c2 illustrates the cross-sectional structure of the transistor MW1 in a channel width direction.

In FIG. 17, regions where reference numerals and hatching patterns are not given show regions formed using an insulator. These regions can be formed using an insulator containing one or more materials selected from aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, tantalum oxide, and the like. Alternatively, these regions can be formed using an organic resin such as a polyimide resin, a polyamide resin, an acrylic resin, a siloxane resin, an epoxy resin, or a phenol resin.

### <Transistors MA1 and MR1>

Here, a planar-type field-effect transistor is used as each of the transistors MA1 and MR1. Each of the transistors MA1 and MR1 is formed using an SOI semiconductor substrate including a single crystal silicon layer. A substrate 400 is a substrate (e.g., a single crystal silicon substrate) that supports the single crystal silicon layer. An insulating layer 401 is a buried oxide layer (BOX layer) for insulating the single crystal silicon layer from the substrate 400. Needless to say, a Si transistor such as the transistor MA1 can be formed using a bulk-type single crystal silicon substrate. The device structure of each of the transistors MA1 and MR1 is not limited to the example of FIG. 17. For example, a 3D transistor (e.g., a fin-type transistor or a Tri-gate type transistor) formed using a convex portion of the semiconductor substrate can be employed. Conductors 420 and 421 have regions functioning as gate electrode of the transistors MA1 and MR1, respectively. Insulating layers 422 and 423 are formed on side surfaces of the conductors 420 and 421. A channel region and an impurity region are formed in a Si-type layer 410 in a self-aligned manner by using the conductors 420 and 421 and the insulating layers 422 and 423 as masks for addition of an impurity. The transistors MA1 and MR1 are covered with an insulating layer 402.

### <Transistor MW1>

The transistor MW1 has a device structure similar to that of the OS transistor 504. The device structure of the transistor MW1 is not limited to this example.

The transistor MW1 is formed over an insulating layer 403. The transistor MW1 includes an OS layer 430 including a channel formation region, conductors 435 to 438, and a gate insulating layer 439. The transistor MW1 is covered with an insulating layer 404 and an insulating layer 405. The OS layer 430 of the transistor MW1 has a three-layer structure of OS layers 431 to 433, which is similar to a three-layer structure of the OS transistor 504 (FIGS. 13A to 13D). The conductor 436 has a region functioning as a gate electrode of the transistor MW1. The conductors 437 and 438 each function as a source electrode or a drain electrode of the transistor MW1.

The insulating layer 403 serving as a base insulating layer of the transistor MW1 is preferably formed using an insulator having a function of preventing diffusion of hydrogen from a lower layer into the OS layer 430. This has an effect of improving reliability of the Si transistor by terminating dangling bonds of silicon in the Si layer by hydrogen. In contrast, as described above, hydrogen serves as an impurity that reduces reliability of the OS layer in the OS transistor. Thus, the insulating layer 403 confines hydrogen in the lower layer and diffuses hydrogen from the lower layer into an upper layer, so that reliability of both the transistor MA1 (Si transistor) and the transistor MW1 (OS transistor) can be improved. The insulating layer 403 can be formed using aluminum oxide, aluminum oxynitride, gallium oxide, gallium oxynitride, yttrium oxide, yttrium oxynitride, hafnium oxide, hafnium oxynitride, or yttria-stabilized zirconia (YSZ), for example. In particular, the aluminum oxide film is preferably used as the base insulating layer because the aluminum oxide film has a high shielding (blocking) effect of preventing penetration of both oxygen and impurities such as hydrogen and moisture.

### <Capacitor CB1>

A region in which a conductor 461 and a conductor 462 overlap with each other with a dielectric provided therebetween functions as the capacitor CM. The conductor 461 has a region functioning as a wiring RWL. The conductor 462 is electrically connected to the gate electrode (the conductor 420) of the transistor MA1 through conductors 463 to 466.

### Embodiment 4

In this embodiment, an electronic component and electronic devices and the like including the electronic component are described as examples of a semiconductor device.

### <Example of Manufacturing Method of Electronic Component>

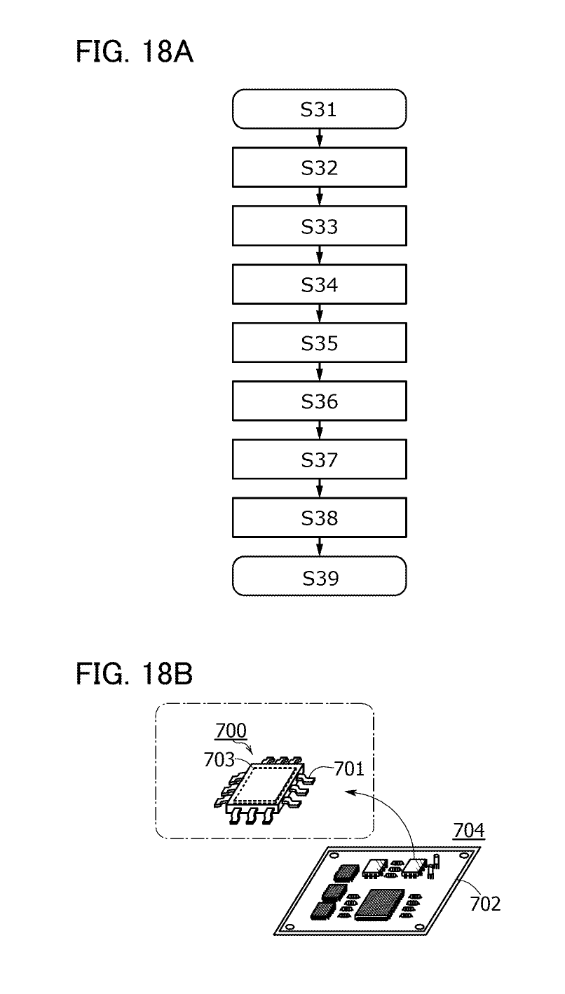

FIG. 18A is a flow chart showing an example of a method for manufacturing an electronic component. The electronic component is also referred to as a semiconductor package or an IC package. This electronic component has a plurality of standards and names depending on a terminal extraction direction and a terminal shape. Examples of the electronic component are described in this embodiment.

A semiconductor device including a transistor is completed by integrating detachable components on a printed wiring board through an assembly process (post-process). The post-process can be finished through steps in FIG. 18A. Specifically, after an element substrate obtained in a wafer process is completed (Step S31), a rear surface of the substrate is ground (Step S32). The substrate is thinned in this step to reduce warpage or the like of the substrate in the wafer process and to reduce the size of the electronic component.

The rear surface of the substrate is ground so that the substrate is divided into a plurality of chips in a dicing process. Then, the divided chips are separately picked up to be mounted on and bonded to a lead frame in a die bonding step (Step S33). In this die bonding step, the chip is bonded to the lead frame by an appropriate method depending on a product, for example, bonding with a resin or a tape. Note that in the die bonding step, the chip may be mounted on an interposer to be bonded.

Then, wire bonding is performed to electrically connect lead of the lead frame to an electrode on the chip with a metal fine line (wire) (Step S34). A silver line or a gold line can be used as the metal fine line. Ball bonding or wedge bonding can be used as the wire bonding.

A molding step is performed to seal the wire bonded chip with an epoxy resin or the like (Step S35). With the molding step, the electronic component is filled with the resin, so that damage to a mounted circuit portion or wire due to mechanical external force can be reduced. Furthermore, deterioration in characteristics due to moisture or dust can be reduced.

Next, the lead of the lead frame is plated. After that, the lead is cut and processed (Step S36). This plating process prevents rust of the lead and facilitates soldering at the time of mounting the chip on a printed wiring board in a later step.

Next, printing (marking) is performed on a surface of the package (Step S37). Through a final inspection step (Step S38), the electronic component is completed (Step S39).

The above electronic component can include the semiconductor device described in the above embodiment. Thus, the electronic component can consume less power and have smaller size.

FIG. 18B is a schematic perspective view of the completed electronic component. FIG. 18B illustrates a schematic perspective view of a quad flat package (QFP) as an example of the electronic component. As illustrated in FIG. 18B, an electronic component 700 includes a lead 701 and a circuit portion 703. The electronic component 700 is mounted on a printed wiring board 702, for example. When a plurality of electronic components 700 are used in combination and electrically connected to each other over the printed wiring board 702, the electronic components 700 can be mounted on an electronic device. A completed circuit board 704 is provided in the electronic device or the like. The electronic component 700 can be used as, for example, a random access memory that stores data or a processing unit that executes a variety of processings, such as a microcontroller unit (MCU) or an RFID tag.

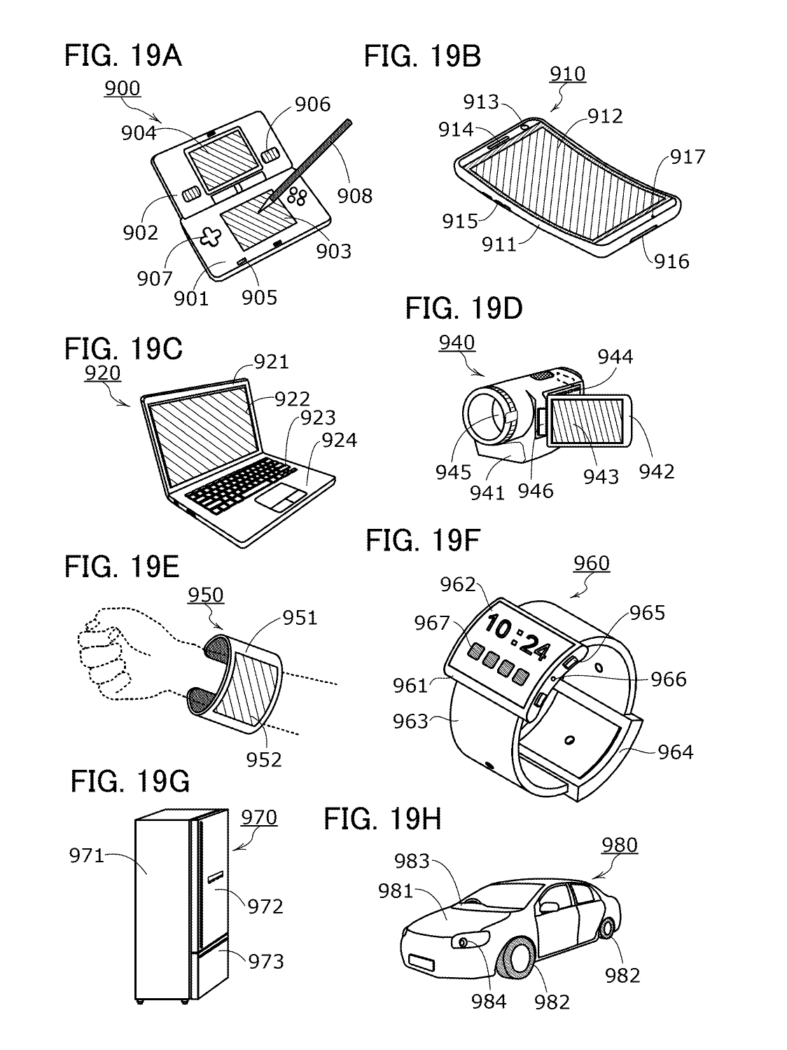

The electronic component 700 can be used as electronic component (IC chip) of electronic devices in a wide variety of fields, such as digital signal processing, software-defined radio systems, avionic systems (electronic devices used in aircraft, such as communication systems, navigation systems, autopilot systems, and flight management systems), ASIC prototyping, medical image processing, voice recognition, encryption, bioinformatics, emulators for mechanical systems, and radio telescopes in radio astronomy. Examples of such an electronic device include display devices, personal computers (PC), or image reproducing devices provided with recording media (typically, devices which reproduce the content of recording media such as digital versatile discs (DVD) and have displays for displaying the reproduced images). Other examples of electronic device that can be equipped with the electronic component in one embodiment of the present invention include mobile phones, game machines including portable game machines, portable data appliances, e-book readers, cameras (e.g., video cameras and digital still cameras), wearable display devices or terminals (e.g., head mounted display devices or terminals, goggle-type display devices or terminals, glasses-type display devices or terminals, armband display devices or terminals, bracelet-type display devices or terminals, and necklace-type display devices or terminals), navigation systems, audio reproducing devices (e.g., car audio systems and digital audio players), copiers, facsimiles, printers, multifunction printers, automated teller machines (ATM), and vending machines. FIGS. 19A to 19H illustrate specific examples of such electronic devices.

### <Electronic Device>

FIGS. 19A to 19F illustrate examples of an electronic device that includes a display portion and is driven by a battery.

A portable game machine 900 in FIG. 19A includes a housing 901, a housing 902, a display portion 903, a display portion 904, a microphone 905, a speaker 906, an operation key 907, and the like. The display portion 903 is provided with a touch screen as an input device, which can be handled with a stylus 908 or the like.

The information terminal 910 in FIG. 19B includes a housing 911, a display portion 912, a microphone 917, a speaker portion 914, a camera 913, an external connection portion 916, an operation button 915, and the like. A display panel that uses a flexible substrate and a touch screen are provided in the display portion 912. The information terminal 910 can be used as, for example, a smartphone, a mobile phone, a tablet information terminal, a tablet PC, or an e-book reader.

A laptop 920 in FIG. 19C includes a housing 921, a display portion 922, a keyboard 923, a pointing device 924, and the like.

A video camera 940 in FIG. 19D includes a housing 941, a housing 942, a display portion 943, operation keys 944, a lens 945, a joint 946, and the like. The operation keys 944 and the lens 945 are provided in the housing 941, and the display portion 943 is provided in the housing 942. The housings 941 and 942 are connected to each other with the joint 946, and an angle between the housings 941 and 942 can be changed with the joint 946. The direction of an image on the display portion 943 may be changed and display and non-display of an image may be switched depending on the angle between the housings 941 and 942.

FIG. 19E illustrates an example of a bangle-type information terminal. An information terminal 950 includes a housing 951, a display portion 952, and the like. The display portion 952 is supported by the housing 951 having a curved surface. A display panel formed with a flexible substrate is provided in the display portion 952, so that the information terminal 950 can be a user-friendly information terminal that is flexible and lightweight.

FIG. 19F illustrates an example of a watch-type information terminal. An information terminal 960 includes a housing 961, a display portion 962, a band 963, a buckle 964, an operation button 965, an input/output terminal 966, and the like. The information terminal 960 is capable of executing a variety of applications such as mobile phone calls, e-mailing, viewing and editing texts, music reproduction, Internet communication, and computer games.

The display surface of the display portion 962 is bent, and images can be displayed on the bent display surface. Furthermore, the display portion 962 includes a touch sensor, and operation can be performed by touching the screen with a finger, a stylus, or the like. For example, by touching an icon 967 displayed on the display portion 962, an application can be started. With the operation button 965, a variety of functions such as time setting, power ON/OFF, ON/OFF of wireless communication, setting and cancellation of a manner mode, and setting and cancellation of a power saving mode can be performed. For example, the functions of the operation button 965 can be set by setting the operating system incorporated in the information terminal 960.

The information terminal 960 can employ near field communication that is a communication method based on an existing communication standard. In that case, for example, mutual communication between the information terminal 960 and a headset capable of wireless communication can be performed, and thus hands-free calling is possible. Moreover, the information terminal 960 includes the input/output terminal 966, and data can be directly transmitted to and received from another information terminal via a connector. Power charging through the input/output terminal 966 is possible. Note that the charging operation may be performed by wireless power feeding without using the input/output terminal 966.

FIG. 19G illustrates an electric refrigerator-freezer as an example of a home electric device. An electric refrigerator-freezer 970 includes a housing 971, a refrigerator door 972, a freezer door 973, and the like.

FIG. 19H is an external view illustrating a structure example of a motor vehicle. A motor vehicle 980 includes a car body 981, wheels 982, a dashboard 983, lights 984, and the like.

An electronic component including the semiconductor device described in the above embodiment is provided in the electronic devices described in this embodiment. Thus, it is possible to provide an electronic device that consumes less power and can operate stably.

### Example 1

In Embodiment 1, the case is described in which leakage current of the processing unit can be efficiently reduced by reducing an overhead caused by normal operation of the semiconductor device when the retention circuit including the OS transistor and the capacitor is provided as the backup circuit. The processing unit 21 on which the cache in FIG. 4A is mounted was fabricated to verify efficient leakage current reduction.

### <Processing Unit (Test Chip)>

A processing unit in which a CPU core and a cache are embedded was fabricated. A chip of this processing unit was formed using an SOI single crystal silicon wafer. An oxide semiconductor layer of an OS transistor was formed using a CAAC-OS. The CAAC-OS was an In—Ga—Zn oxide deposited by a sputtering apparatus. “CAAC-IGZO” in Table 1 is an In—Ga—Zn oxide having a CAAC structure. In this processing unit, the technology node of a CAAC-IGZO transistor is 60 nm and the technology node of a Si transistor is 180 nm. The specifications of this processing unit are shown below.

TABLE 1

| | |
|---|---|
| Fabrication | Si: 180 nm |
| technology | CAAC-IGZO: 60 nm |
| Supply voltage | Si: 1.8 V |
| | CAAC-IGZO: 2.5 V/−1 V |
| Architecture | 32-bit RISC (ARM Cortex-M0) |
| Clock frequency | 30 MHz |
| Backup circuits | Embedded SRAM and flip-flops |
| implementation | |

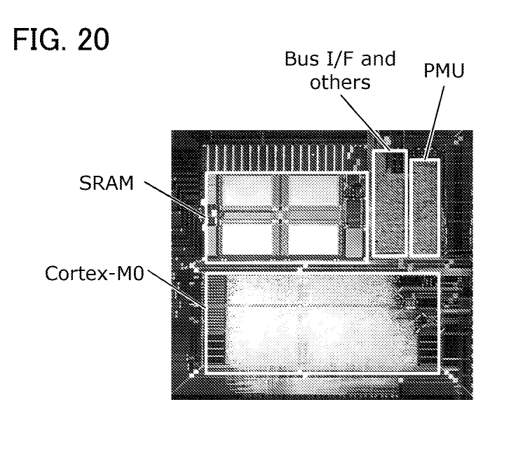

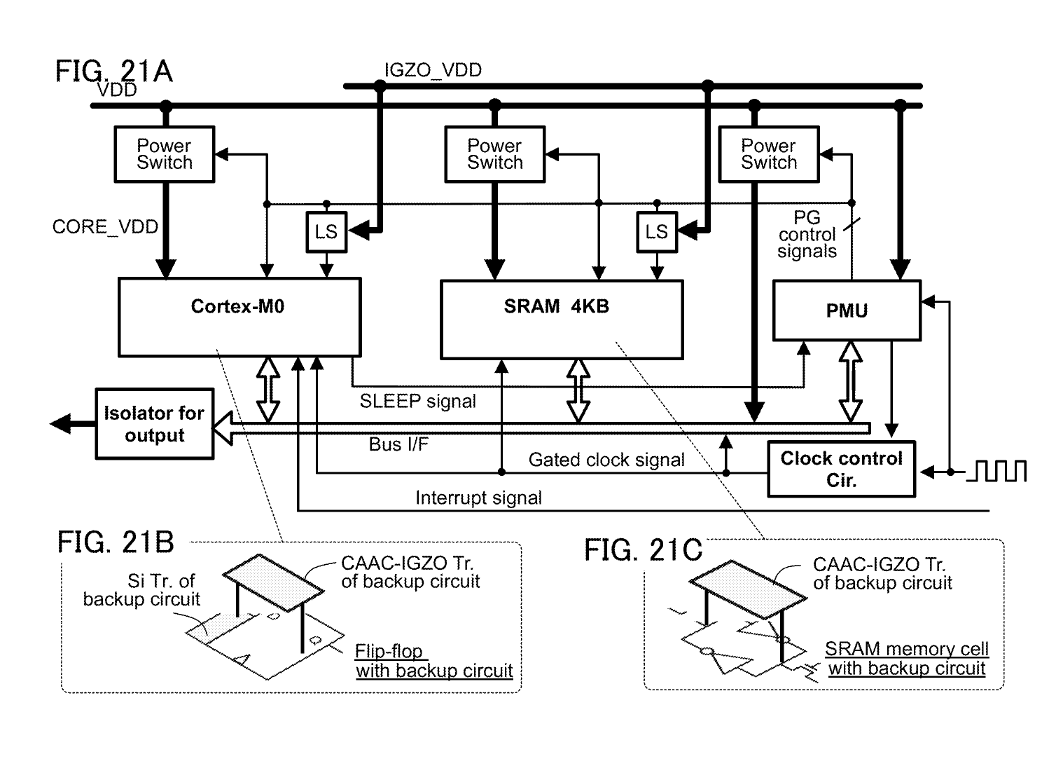

FIG. 20 shows a micrograph of a fabricated processing unit (chip). FIG. 21A is a block diagram of a fabricated processor. The CPU core is ARM Cortex-M0 (Design start edition, where Cortex-MO is a registered trademark). The cache is a 4 Kbyte SRAM. As illustrated in FIG. 21A, this processing unit includes the CPU core (hereinafter referred to as an M0 core), the SRAM, a bus interface (Bus I/F), a clock control circuit, a power switch, a power management unit (PMU), a level shifter (LS), and an isolator. The level shifter adjusts the potential level of a control signal of the OS transistor. A reference clock signal (30 MHz) and an interrupt signal are input to this processing unit from the outside. VDD (1.8 V) and IGZO_VDD (2.5 V) are high power supply potentials input from the outside.

### [Flip-Flop Circuit]

All the flip-flop circuits (841 bits) in the M0 core have circuit configurations similar to that of the storage circuit 100 in FIG. 6 and include backup circuits. As illustrated in FIG. 21B, part of the backup circuit includes a Si transistor and is formed in the same layer as the flip-flop circuit. The CAAC-IGZO transistor is stacked over the flip-flop circuit. Table 2 shows the specifications of the fabricated flip-flop circuit. L denotes channel length, W denotes channel width, and t_{EOX} denotes equivalent oxide film thickness.

TABLE 2

| | |
|---|---|
| CAAC-IGZO | L: 60 nm |
| transistor | W: 40 nm |
| Si transistor | L: 180 nm |
| | W: 4 μm or 6 μm |
| Capacitor | 50 fF (t_{EOX} = 10 nm) |
| Area | 33.8 μm × 61.4 μm |

Backup circuits including CAAC-IGZO transistors are mounted on all the memory cells of the SRAM. Two CAAC-IGZO transistors are used per bit of the memory cell; thus, 65536 CAAC-IGZO transistors are mounted. As illustrated in FIG. 21C, the backup circuit of the memory cell includes only the CAAC-IGZO transistor and a storage capacitor; thus, the whole backup circuit is stacked over the memory cell.

The power switches are provided in the M0 core, the SRAM, and the bus interface to perform power gating. The PMU controls the backup circuits of the flip-flop circuit and the SRAM and the power switches. The power supply potential VDD of a logic circuit is 1.8 V and a high-level potential applied to a gate of the CAAC-IGZO transistor is 2.5 V (VDD_IGZO). The high-level potential is used for compensating a voltage drop due to the threshold voltage of the CAAC-IGZO transistor when data is written to the backup circuit. A potential applied to the gate for turning off the CAAC-IGZO transistor is −1 V and adjusts off-state current.

<SRAM with Backup Circuit>

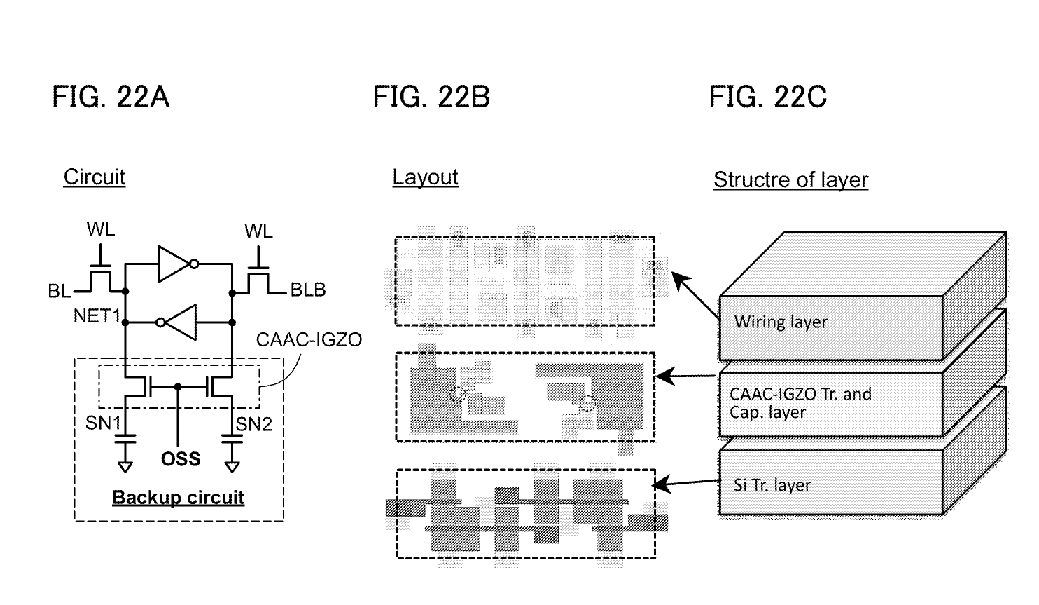

FIGS. 22A to 22C illustrate an SRAM memory cell structure. FIG. 22A is a circuit diagram of the memory cell. FIG. 22B is a layout diagram of the memory cell. FIG. 22C schematically illustrates the layered structure of the memory cell.

The backup circuit mounted on the SRAM memory cell includes two CAAC-IGZO transistors and two storage capacitors. The backup circuit is connected to an inverter loop. The CAAC-IGZO transistors and the storage capacitors are formed over a memory cell of the Si transistor. In the OS transistor/capacitor layer in FIG. 22B, the centers of circles represent the CAAC-IGZO transistors, and the storage capacitors occupy the other regions. A wiring layer is formed over the OS transistor/capacitor layer. FIG. 22B indicates that memory cell layout area does not increase due to addition of the backup circuit. Table 3 shows the specifications of the fabricated SRAM memory cell.

TABLE 3

| | |
|---|---|
| CAAC-IGZO | L: 60 nm |
| transistor | W: 40 nm |
| Si transistor | L: 180 nm |
| | W: 1.6 μm or 32 μm |
| Capacitor | 51 fF (t_{EOX} = 10 nm) |
| Area | 98.6 μm² (5.8 μm × 17.0 μm) |

### <SRAM Module>

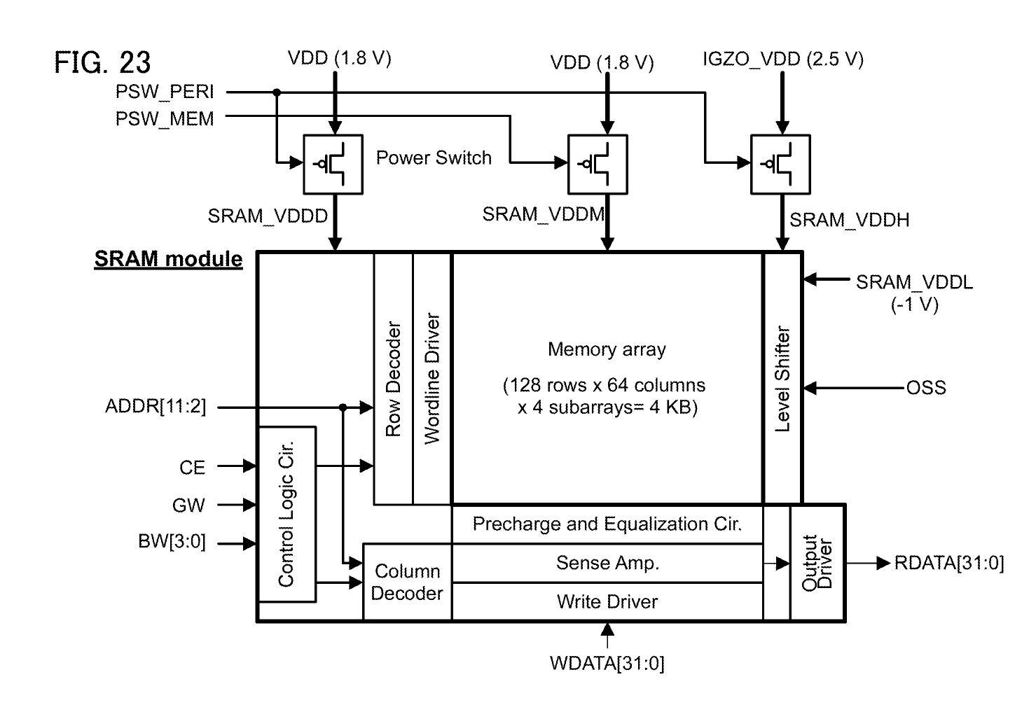

FIG. 23 is a block diagram of an SRAM module. The SRAM module (also simply referred to as an SRAM) includes a memory array, a peripheral circuit, and a level shifter. The memory array includes four subarrays (128 rows×64 columns). As illustrated in FIG. 23, the peripheral circuit includes a control logic circuit, a row decoder, a word line driver, a column decoder, a precharge and equalization circuit, a sense amplifier, a write driver, and an output driver. ADDR is an address signal, WDATA is a data signal written to the memory array, and RDATA is a data signal read from the memory array. CE, GW, and BW are command signals processed by the control logic circuit. A signal PSW_PERI is a control signal of a power switch for the peripheral circuit and a power switch for the level shifter. A signal PSW_MEM is a control signal of a power switch for the memory array. The PMU generates the signal PSW_PERI and the signal PSW_MEM. In the case where the control signals (the signal PSW_PERI and the signal PSW_MEM) are at low levels, the power switch of this processing unit supplies power. In the case where the control signals (the signal PSW_PERI and the signal PSW_MEM) are at high levels, the power switch of this processing unit stops power supply.

The SRAM has three power domains and corresponding power switches. This processing unit uses coarse-grained header-type power switches. The high power supply potentials of the peripheral circuit and the memory array are SRAM_VDDD (1.8 V) and SRAM_VDDM (1.8 V), respectively. The power supply potentials of the level shifter are SRAM_VDDH (2.5 V) and SRAM_VDDL (−1 V). The level shifter changes the potential level of the signal OSS input from the PMU.

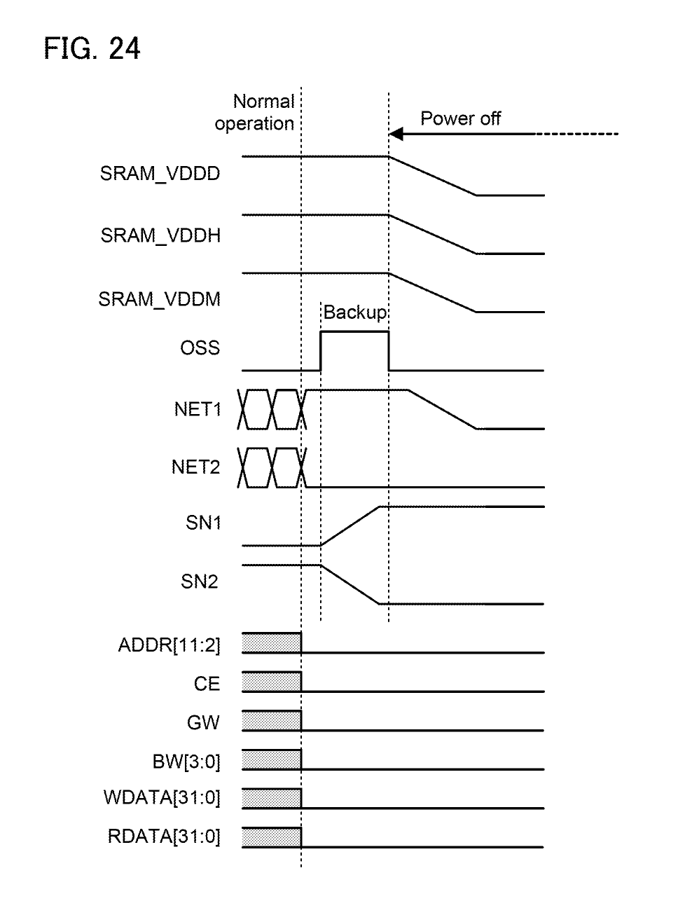

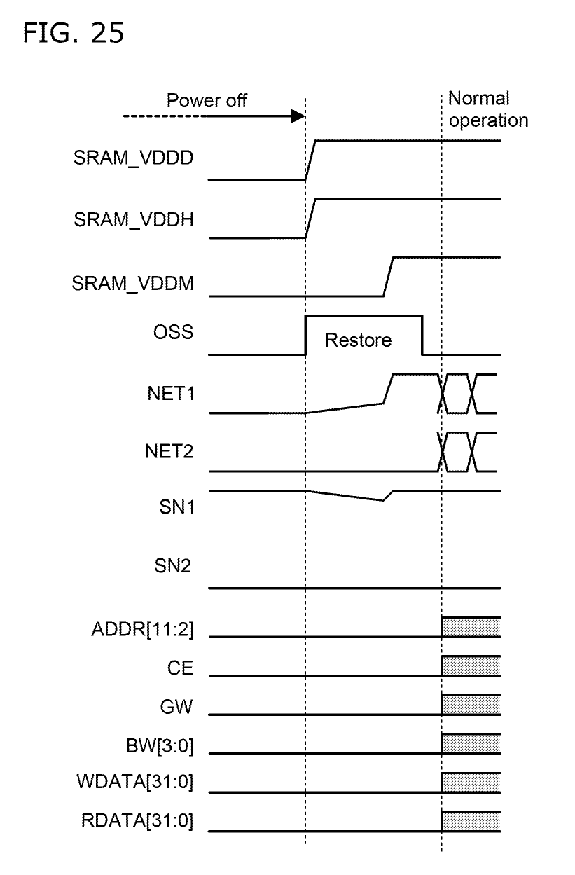

FIG. 24 and FIG. 25 are timing charts of power gating operation of the SRAM module. FIG. 24 shows operation of stopping power supply by power gating, and FIG. 25 shows operation of recovering from a power-off state to a normal state.

As described with reference to FIG. 9, in data backup and restore operation of the memory array, only the gate signal (OSS) of the CAAC-IGZO transistor is controlled. Power supply can be stopped immediately after data is stored in the backup circuit. The PMU controls operation of the power switch and the signal OSS. The storage capacitor of the backup circuit is charged or discharged while the signal OSS is at a high level; thus, data backup time is mainly determined by the electrical characteristics of the CAAC-IGZO transistor and the capacitance of the storage capacitor.

Data restore time is the sum of time to stabilize a power supply line and time to restore data from the backup circuit to the memory array. In order to recover the normal operation, the power switches for the memory array and the peripheral circuit are turned on, and then, the signal OSS is set at a high level to restore data. Next, the power switch for the memory cell is turned on while the signal OSS is at a high level. When a power supply line for supplying SRAM_VDDM is stabilized, the SRAM recovers to the state before power-off. The time to stabilize the power supply line varies depending on load capacitance due to the power supply line.

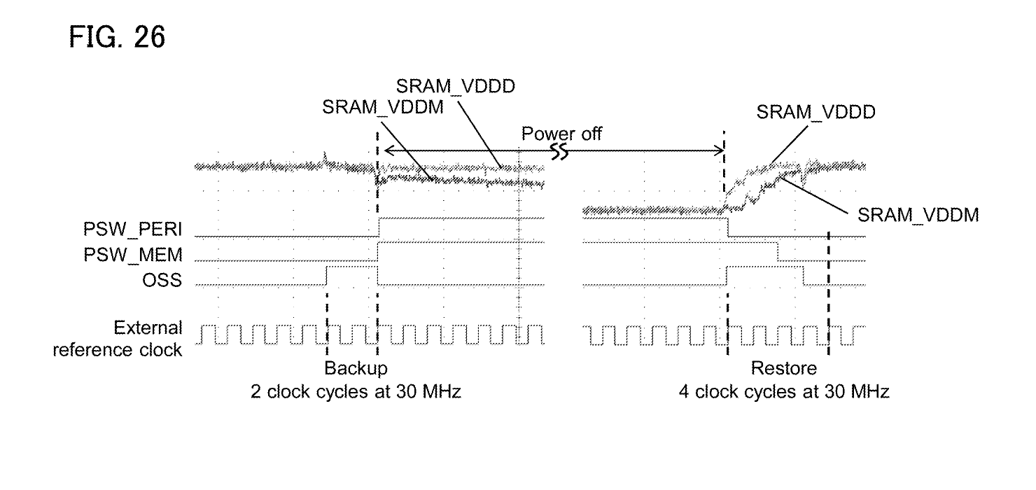

The minimum time required for backup and restore in the SRAM were evaluated. Results are shown in FIG. 26. All the data of the memory array was backed up in 2 clock cycles (approximately 66 ns). All the data was restored in 4 clock cycles (approximately 132 ns) after power-on. After the data was restored, normal operation was able to be performed. Similar evaluation was performed under the condition where temperature is 85° C. and the power supply potential VDD is reduced by 10%. The time required for backup and restore was not changed even under this condition. The fabricated SRAM can recover from the power-off state in a short time in this manner; thus, the fabricated SRAM can perform temporal fine-grained power gating and is suitable for an embedded SRAM. For example, the 16 Kbyte memory array is divided into blocks in which power gating can be performed every 4 Kbytes. With such a structure, power supply to the block that is not accessed is stopped by power gating. The block in which power supply is stopped can recover in 4 clock cycles to be used when needed. Leakage current becomes higher as the number of SRAM bits becomes larger; thus, setting the block in a resting state even for a short time is effective in reducing the standby power of the processor. In this manner, this processing unit can perform spatially-divided power gating; thus, not only standby power but also power consumption in the normal operation can be effectively reduced.

### <Flip-Flop Circuit>

The backup and restore time was shortened by the operation method in FIG. 7. When charge for data retention is precharged to the backup circuit in normal operation, the backup time can be shortened. This is because the discharge speed of the n-channel transistor is higher than the charge speed of the n-channel transistor. When the precharge control signal OSC is at a low level and the gate control signal OSG of the CAAC-IGZO transistor is at a high level, a retention node FN of the backup circuit is charged to a high level. When OSC is set at a high level in power gating operation, the potential of the retention node FN is changed depending on data on the slave side of the flip-flop circuit. The storage capacitor maintains charge when the data of the flip-flop circuit is “1” and is discharged when the data of the flip-flop circuit is “0”. After that, backup operation is completed by setting OSG at a low level. Power supply can be stopped immediately after the backup operation. Data is restored by operating a read circuit including Si transistors (MA1 and MR1 in FIG. 6). Data is restored on the master side of the flip-flop circuit by setting the signal OSR at a high level after resetting the flip-flop circuit.

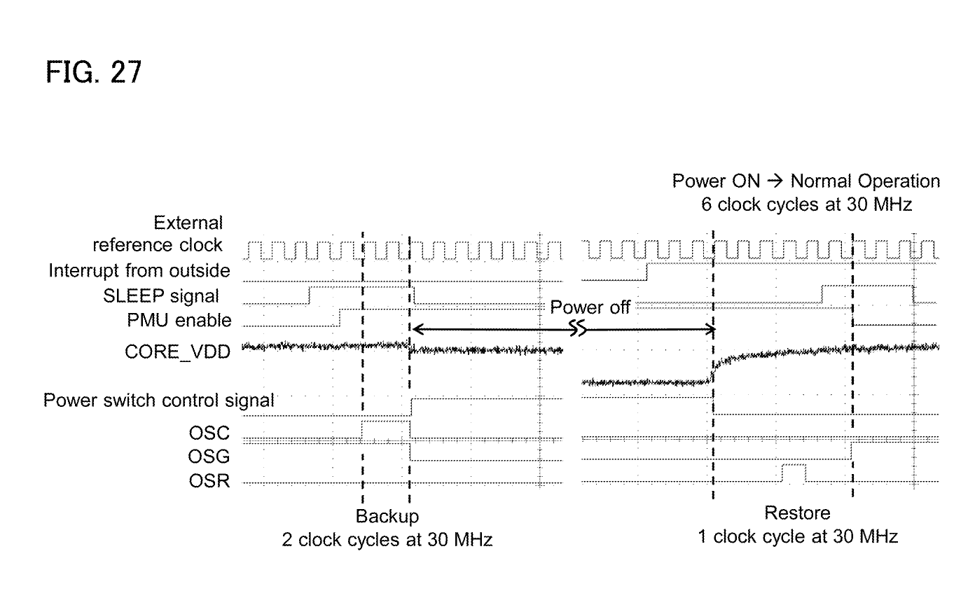

The minimum time required for backup and restore in a flip-flop circuit was evaluated. Results are shown in FIG. 27. As in the SRAM, data was backed up in 2 clock cycles (approximately 66 ns) in the flip-flop circuit. Data restore operation can be completed in 1 clock cycle. The rise time of the power supply line was increased due to a decoupling capacitor; thus, it took 6 clock cycles to perform normal operation after the power switch is turned on. Similar evaluation was performed under the condition where temperature is 85° C. and the power supply potential VDD is reduced by 10%. The restore time was increased by 3 clock cycles because the influence of the characteristics of the Si transistor was large.

As illustrated in FIG. 27, a SLEEP signal was set at a high level while the power supply potential was raised. This indicates that the M0 core recovers to the state before power-off, that is, a state in which an instruction to output the SLEEP signal is executed. In other words, it is confirmed that this processing unit can perform power gating by providing a flip-flop circuit with a backup circuit.

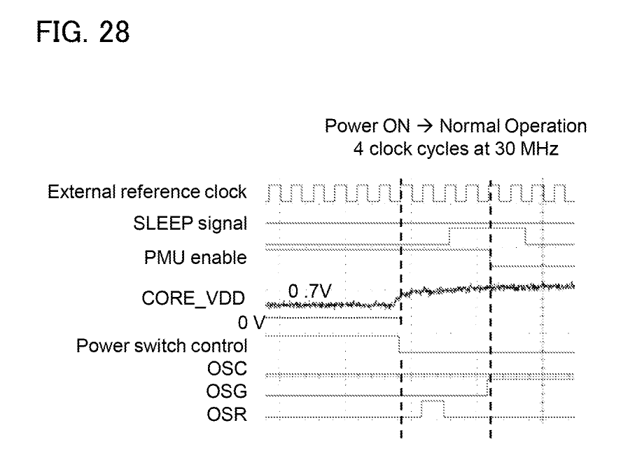

As illustrated in FIG. 27, when power supply is stopped in the resting state, it takes comparatively long time to raise the power supply potential (CORE_VDD) of the M0 core. Thus, whether the recovery time of the M0 core can be shortened by voltage scaling was verified. Specifically, operation of restarting power supply from the resting state in which CORE_VDD is 0.7 V without being lowered to 0 V was examined. In this operation, the FF performed voltage scaling operation while data was backed up to the backup circuit. Note that 0.7 V was obtained by actual evaluation. FIG. 28 shows evaluation results.

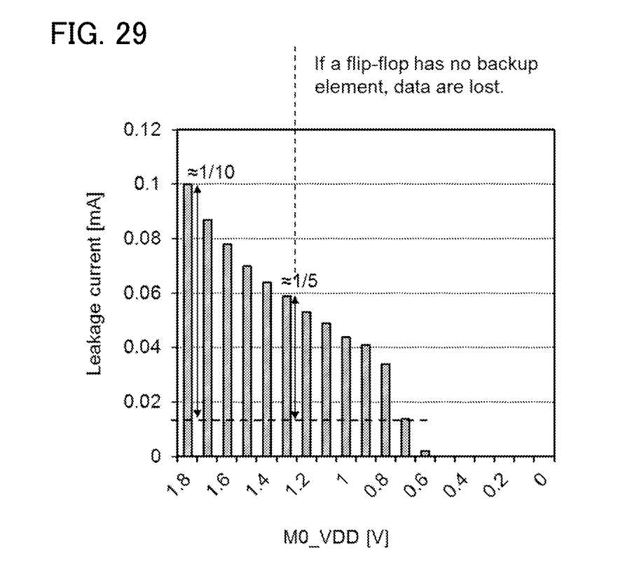

As illustrated in FIG. 28, CORE_VDD was raised in 1 clock cycle from 0.7 V. In addition, the flip-flop circuit can perform normal operation in 4 clock cycles after the power switch is turned on. As illustrated in FIG. 29, in the case where the flip-flop circuit did not include a backup mechanism, internal data was lost when CORE_VDD was lower than or equal to 1.3 V. Thus, it is impossible to lower CORE_VDD to 0.7 V in the resting state in a processing unit that does not include a backup mechanism. In this processing unit, the flip-flop circuit includes a backup circuit that can retain data even in the power-off state; thus, it is possible to lower CORE_VDD to 0.7 V in the resting state.

FIG. 29 shows the relationship between CORE_VDD and leakage current. In this processing unit, leakage current when CORE_VDD was 0.7 V was approximately 1/10 of that when CORE_VDD was 1.8 V and was approximately ⅕ of that when CORE_VDD was 1.3 V. Thus, in the case where this processing unit is powered on in a short time immediately after being set in a resting state, restore operation overhead time can be shortened by performing not power gating in which CORE_VDD is lowered to 0 V but voltage scaling in which CORE_VDD higher than 0 V is supplied in the resting state. As described in Embodiment 1, when power gating is combined with voltage scaling, opportunities of making this processing unit in the resting state are increased, so that the power consumption of this processing unit can be efficiently reduced.

### <Evaluation of Power Reduction>

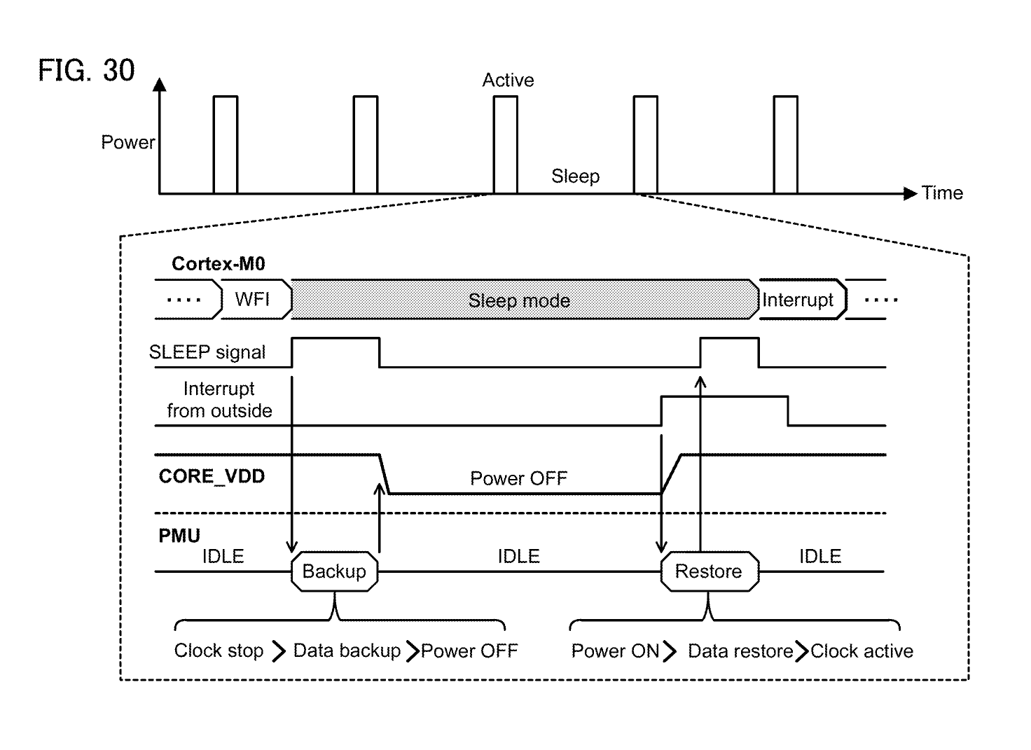

The power consumption of this processing unit was evaluated. FIG. 30 schematically shows operation of this processing unit using an evaluation program. An Active mode and a Sleep mode are repeated periodically. In the evaluation program, the power modes are a power-on mode and a power-off mode. WFI (instruction to set the M0 core in the Sleep mode) is executed, so that the SLEEP signal is output from the M0 core. The PMU starts backup operation control using the SLEEP signal as a trigger. An interrupt signal from the outside is used for powering on the M0 core. The PMU starts restore operation using the interrupt signal as a trigger. When data is restored to the flip-flop circuit, the M0 core executes WFI and outputs the SLEEP signal. When the M0 core starts interrupt operation, the SLEEP signal is set at a low level and the Sleep mode is terminated. Note that the Active mode corresponds to a normal mode in which the normal operation is executed.

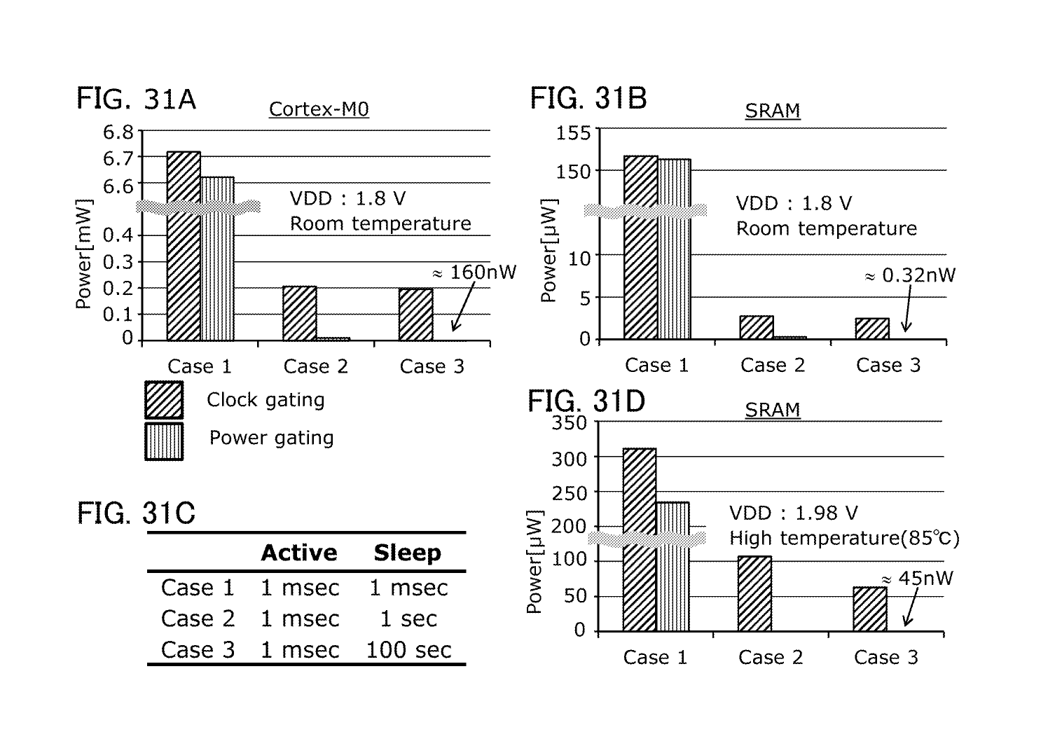

On the assumption of a processing unit for a sensor, three cases with different Sleep mode times shown in FIG. 31C were set. In the three cases, the Active time is approximately 1 ms, and the M0 core executes an instruction to access the SRAM and an external interface. In Case 1, the Sleep time is 1 ms. It is assumed that an interrupt signal is input from an acceleration sensor every 1 ms. In Case 2, the Sleep time is 1 s. It is assumed that the processing unit obtains data of a temperature sensor every one second. In Case 3, the Sleep time is 100 s. It is assumed that the processing unit is in the resting state for a long time.

Power consumption in Case 1, Case 2, and Case 3 was measured. Power consumption in the case of clock gating was compared with that in the case of power gating. FIG. 31A shows measurement results of the power consumption of the M0 core, and FIG. 31B shows measurement results of the power consumption of the SRAM. Measurement was performed at room temperature and a power supply potential VDD of 1.7 V. In Cases 1 to 3, power gating was able to reduce much power than clock gating. In the case of power gating, in Case 3, the power consumption of the M0 core was approximately 160 nW and the power consumption of the SRAM was approximately 0.32 nW. In this processing unit, power gating was able to reduce standby power by 99% or more. When the capacitance of the SRAM becomes larger, the amount of power of the SRAM reduced by power gating becomes larger. FIG. 31D shows measurement results of the power consumption of the SRAM in a leakage worst case. In the leakage worst case, the power reduction effect by power gating is apparent. In the case of power gating, the power consumption of the SRAM in Case 3 was approximately 45 nW. In the leakage worst case, the chip temperature is high (85° C.) and the power supply potential VDD is increased by 10%, that is, 1.98 V.

Energy required to control the CAAC-IGZO transistor was evaluated. The power consumption of a 2.5 V power supply line for controlling the CAAC-IGZO transistor was measured, and energy required to control backup operation and restore operation was estimated. The SRAM memory cell energy was 123 fJ/bit and the energy of the flip-flop circuit in the MO core was 150 fJ/bit. Energy required to charge the storage capacitor of the backup circuit depends on the capacitance of the capacitor and voltage. When the storage capacitance was 50 fF and the voltage was 1.8 V, the maximum energy was 81 fJ. The backup circuit including the CAAC-IGZO transistor has a similar configuration as that in the DRAM memory cell, and energy of data write and read operation is low. It is very effective to reduce energy consumed by the backup circuit in reducing power.

The CAAC-IGZO transistor has extremely low off-state current. It was verified that this processing unit including a 60 nm-CAAC-IGZO transistor was able to perform power gating for a long time of ten days. As an example, measured off-state current per micrometer of channel width at 85° C. was 6 yoctoamperes (6×10⁻²⁴) A/μm. This shows that when the storage capacitance is at least 10 fF, the backup circuit can retain data for ten years at 85° C. That is, the backup circuit in one embodiment of the present invention can be used as a nonvolatile memory.

Note that in a storage circuit that utilizes the extremely low off-state current of a transistor including an oxide semiconductor layer in a channel portion, predetermined voltage might be continuously supplied to the transistor including the oxide semiconductor layer in a data retention period. For example, voltage that turns off the transistor completely might be continuously supplied to a gate of the transistor. Alternatively, voltage that shifts the threshold voltage of the transistor to make the transistor in a normally-off state may be continuously supplied to a back gate of the transistor. In such a case, the voltage is supplied to the storage circuit in the data retention period. However, little power is consumed because almost no current flows. Because of little power consumption, even if the predetermined voltage is supplied to the storage circuit, the storage circuit can be regarded as being substantially nonvolatile.

In this example, it is confirmed that with the use of the backup circuit including the OS transistor, this processing unit including the Cortex-M0 core and the embedded SRAM can effectively reduce standby power by a combination of power gating and voltage scaling.

### REFERENCE NUMERALS

BKC1: circuit, BKC2: circuit, BKC10: circuit, BKC20: circuit, CB1: capacitor, CB2: capacitor, CB11: capacitor, CB12: capacitor, FN1: node, FN2: node, INV21: inverter circuit, INV22: inverter circuit, M21: transistor, M22: transistor, MA1: transistor, MA2: transistor, MC1: transistor, MC2: transistor, MR1: transistor, MW1: transistor, MW2: transistor, MW11: transistor, MW12: transistor, MemC1: circuit, MemC2: circuit, MemC20: circuit, NB1: node, NET1: node, NET2: node, NK1: node, NR1: node, PCC10: circuit, RTC10: circuit, SMC20: circuit, SN1: node, SN2: node, 10: power supply circuit, 20: processing unit (PU), 21: processing unit (PU), 30: processor core, 31: storage circuit, 32: combinational circuit, 35: power supply line, 40: cache, 41: memory array, 42: peripheral circuit, 43: control circuit, 45: memory cell, 60: power management unit (PMU), 61: timer circuit, 65: clock control circuit, 70: power switch (PSW), 71: power switch (PSW), 80: terminal, 81: terminal, 82: terminal, 83: terminal, 100: storage circuit, 110: flip-flop circuit (FF), 120: memory cell, 130: processor core, 131: control unit, 132: program counter, 133: pipeline register, 134: pipeline register, 135: register file, 136: arithmetic logic unit (ALU), 137: data bus, 400: substrate, 401: insulating layer, 402: insulating layer, 403: insulating layer, 404: insulating layer, 405: insulating layer, 410: Si layer, 420: conductor, 421: conductor, 422: insulating layer, 423: insulating layer, 430: oxide semiconductor (OS) layer, 431: oxide semiconductor (OS) layer, 432: oxide semiconductor (OS) layer, 433: oxide semiconductor (OS) layer, 435: conductor, 436: conductor, 437: conductor, 438: conductor, 439: gate insulating layer, 451: layer, 452: layer, 461: conductor, 462: conductor, 501: OS transistor, 502: OS transistor, 503: OS transistor, 504: OS transistor, 505: OS transistor, 506: OS transistor, 510: substrate, 511: insulating layer, 512: insulating layer, 513: insulating layer, 514: insulating layer, 515: insulating layer, 520: OS layer, 521: OS layer, 522: OS layer, 523: OS layer, 530: conductive layer, 531: conductive layer, 541: conductive layer, 542: conductive layer, 551: layer, 552: layer, 700: electronic component, 701: lead, 702: printed wiring board, 703: circuit portion, 704: circuit board, 900: portable game machine, 901: housing, 902: housing, 903: display portion, 904: display portion, 905: microphone, 906: speaker, 907: operation key, 908: stylus, 910: information terminal, 911: housing, 912: display portion, 913: camera, 914: speaker portion, 915: button, 916: external connection portion, 917: microphone, 920: laptop, 921: housing, 922: display portion, 923: keyboard, 924: pointing device, 940: video camera, 941: housing, 942: housing, 943: display portion, 944: operation key, 945: lens, 946: joint, 950: information terminal, 951: housing, 952: display portion, 960: information terminal, 961: housing, 962: display portion, 963: band, 964: buckle, 965: operation button, 966: input/output terminal, 967: icon, 970: electric refrigerator-freezer, 971: housing, 972: refrigerator door, 973: freezer door, 980: motor vehicle, 981: car body, 982: wheel, 983: dashboard, and 984: light.

This application is based on Japanese Patent Application serial No. 2014-127211 filed with Japan Patent Office on Jun. 20, 2014 and Japanese Patent Application serial No. 2014-167002 filed with Japan Patent Office on Aug. 19, 2014, the entire contents of which are hereby incorporated by reference.

1. A semiconductor device comprising:
a power supply circuit;
a power management unit;
an arithmetic processing circuit; and
a power switch,
wherein the arithmetic processing circuit includes a first circuit and a second circuit,
wherein the first circuit is capable of retaining data generated in the arithmetic processing circuit,
wherein the second circuit is capable of backing up and retaining data retained in the first circuit,
wherein the second circuit is capable of restoring backed up data to the first circuit,
wherein the power switch is capable of controlling supply of a power supply potential to the arithmetic processing circuit, the power supply potential being generated in the power supply circuit,
wherein the power supply circuit is capable of generating a first power supply potential and a second power supply potential,
wherein the power management unit is capable of controlling supply of the power supply potential to the arithmetic processing circuit by controlling operation of the power supply circuit and the power switch,
wherein the power management unit has a plurality of management modes including a first mode, a second mode, and a third mode,
wherein the first mode is a mode in which the first power supply potential is supplied,
wherein the second mode is a mode in which the second power supply potential is supplied,
wherein the third mode is a mode in which supply of the first power supply potential and the second power supply potential is stopped,
wherein the second power supply potential is lower than the first power supply potential,
wherein the second power supply potential is capable of erasing data retained in the first circuit,
wherein the power management unit includes a third circuit being capable of measuring time, and
wherein the power management unit is capable of:
transferring from the first mode to the second mode in response to a first signal generated in the arithmetic processing circuit;
controlling data backup operation from the first circuit to the second circuit in response to the first signal;
transferring from the second mode to the third mode in response to a second signal generated in the third circuit;
transferring from the third mode to the first mode in response to a third signal; and
controlling data restore operation from the second circuit to the first circuit in response to the third signal.

2. The semiconductor device according to claim 1, wherein the first circuit is a flip-flop circuit.

3. The semiconductor device according to claim 1,
wherein the second circuit includes a first transistor and a capacitor,
wherein the capacitor is electrically connected to one of a source and a drain of the first transistor,
wherein conduction of the first transistor is controlled by the power management unit, and
wherein a channel of the first transistor includes an oxide semiconductor.

4. An electronic component comprising the semiconductor device according to claim 1, wherein the electronic component comprises a lead.

5. An electronic device comprising the semiconductor device according to claim 1, wherein the electronic device comprises at least one of a display device, a touch panel, a microphone, a speaker, an operation key, and a housing.

6. A semiconductor device comprising:
a power supply circuit;
a power management unit;
an arithmetic processing circuit; and
a power switch,
wherein the power supply circuit is capable of generating a power supply potential,
wherein the power switch is capable of controlling supply of the power supply potential to the arithmetic processing circuit,
wherein the arithmetic processing circuit includes a first circuit and a second circuit,
wherein the first circuit is capable of retaining data generated in the arithmetic processing circuit,
wherein the second circuit is capable of:
backing up and retaining data retained in the first circuit;
restoring backed up data to the first circuit, and
wherein the power management unit is capable of:
controlling data backup operation from the first circuit to the second circuit;
controlling data restore operation from the second circuit to the first circuit;
controlling operation of the power switch; and
controlling a change in a value of the power supply potential generated in the power supply circuit.

7. The semiconductor device according to claim 6, wherein the first circuit is a flip-flop circuit.

8. The semiconductor device according to claim 6,
wherein the second circuit includes a first transistor and a capacitor,
wherein the capacitor is electrically connected to one of a source and a drain of the first transistor,
wherein conduction of the first transistor is controlled by the power management unit, and
wherein a channel of the first transistor includes an oxide semiconductor.

9. An electronic component comprising the semiconductor device according to claim 6, wherein the electronic component comprises a lead.

10. An electronic device comprising the semiconductor device according to claim 6, wherein the electronic device comprises at least one of a display device, a touch panel, a microphone, a speaker, an operation key, and a housing.
